(19) United States
(12) Patent Application Publication
(10) Pub. No.: US 2024/0047444 A1
(43) Pub. Date: Feb. 8, 2024

(54) DISPLAY DEVICE

(71) Applicant: LG Display Co., Ltd., Seoul (KR)

(72) Inventors: JongBeom LEE, Paju-si (KR); SunHwa LEE, Goyang-si (KR); ByungHyun LEE, Paju-si (KR); Soyi LEE, Paju-si (KR); Seeun KIM, Seoul (KR)

(21) Appl. No.: 18/222,938

(22) Filed: Jul. 17, 2023

(30) Foreign Application Priority Data
Aug. 2, 2022 (KR) 10-2022-0096012

(51) Int. Cl. H01L 25/16; G09G 3/32; H01L 33/62; H01L 23/00

(52) U.S. Cl. CPC H01L 25/167; G09G 3/32; H01L 33/62; H01L 24/29; H01L 24/32; G09G 2300/0842; G09G 2300/0819; G09G 2300/0861; H01L 2224/32145; H01L 2224/29017

(57) ABSTRACT

A display device includes a stretchable lower substrate; a pattern layer disposed on the lower substrate and including a plurality of main plate patterns, a plurality of sub-plate patterns, and a plurality of line patterns; a plurality of sub-pixels disposed on each of the plurality of main plate patterns; and an additional sub-pixel disposed on each of the plurality of sub-plate patterns, wherein only the additional sub-pixels of some sub-plate patterns among the plurality of sub-plate patterns include light emitting elements. Therefore, the display device can be repaired by selectively forming light emitting elements in additional sub-pixels according to whether the plurality of sub-pixels are defective or not.

### CROSS-REFERENCE TO RELATED APPLICATION

This application claims the benefit of and priority to Republic of Korea Patent Application No. 10-2022-0096012 filed on Aug. 2, 2022, in the Republic of Korea, which is hereby incorporated by reference in its entirety.

### BACKGROUND

### Technical Field

The present disclosure relates to a display device, and more particularly, to a stretchable display device capable of being repaired when a defect occurs therein.

### Discussion of the Related Art

Display devices used for a computer monitor, a TV, a mobile phone, and the like include an organic light emitting display (OLED) that emits light by itself, a liquid-crystal display (LCD) that requires a separate light source, and the like.

Such display devices are being applied to more and more various fields including not only a computer monitor and a TV, but personal mobile devices, and thus, display devices having a reduced volume and weight while having a wide active area are being studied.

Recently, a display device manufactured to be stretchable in a specific direction and changeable into various shapes by forming a display unit, lines, and the like on a flexible substrate such as plastic that is a flexible material has received considerable attention as a next-generation display device.

### SUMMARY

An aspect of the present disclosure is to provide a display device allowing for repair of defective sub-pixels when the defective sub-pixels occur.

Another aspect of the present disclosure is to provide a display device capable of being repaired even if a damage occurs when removing a light emitting diode (LED) from a defective sub-pixel.

Still another aspect of the present disclosure is to provide a display device in which additional sub-pixels can be formed without adding a separate area for repair.

Still another aspect of the present disclosure is to provide a display device in which additional sub-pixels can be formed without limitation to design areas of main plate patterns and line patterns.

Objects of the present disclosure are not limited to the above-mentioned objects, and other objects, which are not mentioned above, can be clearly understood by those skilled in the art from the following descriptions.

A display device according to an exemplary embodiment of the present disclosure includes a stretchable lower substrate; a pattern layer disposed on the lower substrate and including a plurality of main plate patterns, a plurality of sub-plate patterns, and a plurality of line patterns; a plurality of sub-pixels disposed on each of the plurality of main plate patterns; an additional sub-pixel disposed on each of the plurality of sub-plate patterns; and a plurality of connection lines disposed on each of the plurality of line patterns to connect the plurality of sub-pixels and the additional sub-pixel, wherein the additional sub-pixels of some sub-plate patterns among the plurality of sub-plate patterns include light emitting elements. Therefore, according to the present disclosure, the display device can be repaired by selectively forming light emitting elements in additional sub-pixels according to whether the plurality of sub-pixels are defective or not.

A display device according to another exemplary embodiment of the present disclosure includes a stretchable lower substrate; a pattern layer disposed on the lower substrate and including a plurality of main plate patterns, a plurality of sub-plate patterns, and a plurality of line patterns; a plurality of sub-pixels disposed on each of the plurality of main plate patterns and each including a pixel circuit; an additional sub-pixel disposed on each of the plurality of sub-plate patterns and including the pixel circuit; a plurality of lines disposed in each of the plurality of sub-pixels and the additional sub-pixel and connected to the pixel circuit; and a plurality of connection lines disposed on each of the plurality of line patterns and connecting the plurality of lines of the plurality of main plate patterns and the plurality of lines of the sub-plate patterns, wherein the plurality of main plate patterns are disposed in different rows and different columns from those of the plurality of sub-plate patterns. Accordingly, according to the present disclosure, a display device can be repaired by forming sub-plate patterns for repair in empty spaces where a plurality of main plate patterns are not disposed, when the display device is defective.

Other detailed matters of the exemplary embodiments are included in the detailed description and the drawings.

According to the present disclosure, instead of securing a separate area for repair, additional sub-pixels for repair can be formed in empty spaces between main plate patterns.

According to the present disclosure, since a repair LED is transferred to an additional sub-pixel, repair can be performed regardless of damage to a connection pad or the like when removing an LED from a defective sub-pixel.

According to the present disclosure, an additional sub-pixel is formed in an area unrelated to a design area of a sub-pixel and a connection line, so that a display device can be repaired when the display device is defective.

The effects according to the present disclosure are not limited to the contents exemplified above, and more various effects are included in the present specification.

### BRIEF DESCRIPTION OF THE DRAWINGS

FIG. 1 is a plan view of a display device according to an exemplary embodiment of the present disclosure.

FIG. 2 is an enlarged plan view of an active area of the display device according to an exemplary embodiment of the present disclosure.

FIG. 3 is a cross-sectional view taken along III-III′ of FIG. 2 according to an exemplary embodiment of the present disclosure.

FIG. 4 is a cross-sectional view taken along IV-IV′ of FIG. 2 according to an exemplary embodiment of the present disclosure.

FIG. 5 is a cross-sectional view taken along V-V′ of FIG. 2 according to an exemplary embodiment of the present disclosure.

FIG. 6 is a cross-sectional view taken along VI-VI′ of FIG. 2 according to an exemplary embodiment of the present disclosure.

FIG. 7 is a circuit diagram of a plurality of sub-pixels of the display device according to an exemplary embodiment of the present disclosure.

FIG. 8 is a circuit diagram of an additional sub-pixel of the display device according to an exemplary embodiment of the present disclosure.

FIG. 9 is a diagram for explaining transmission paths of various signals in the display device according to an exemplary embodiment of the present disclosure.

FIG. 10 is an enlarged plan view of the display device according to an exemplary embodiment of the present disclosure.

FIG. 11 is a cross-sectional view of a defective sub-pixel of the display device according to an exemplary embodiment of the present disclosure.

FIG. 12 is a cross-sectional view of an additional sub-pixel of the display device according to an exemplary embodiment of the present disclosure.

FIG. 13 is a circuit diagram illustrating sub-pixels and an additional sub-pixel of the display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

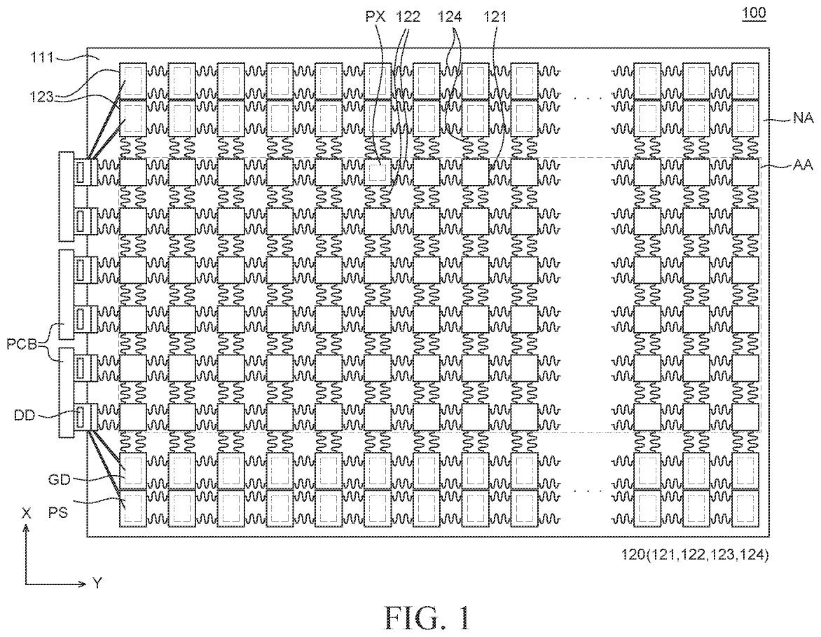

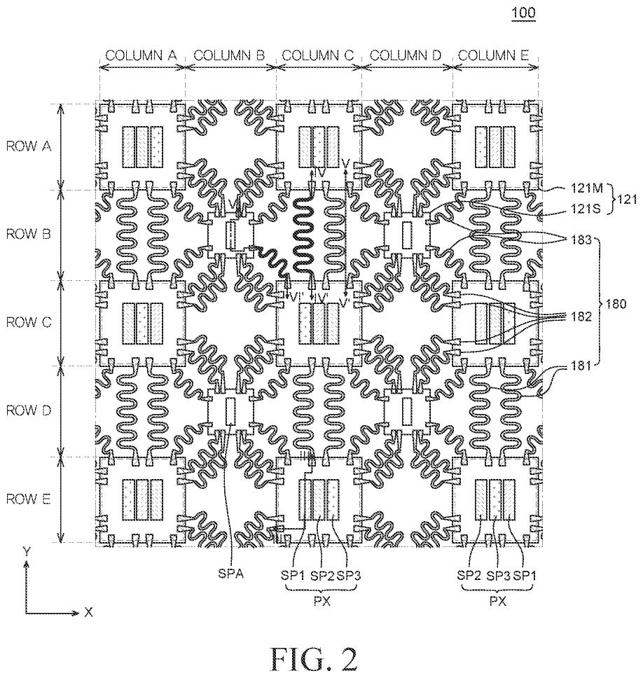

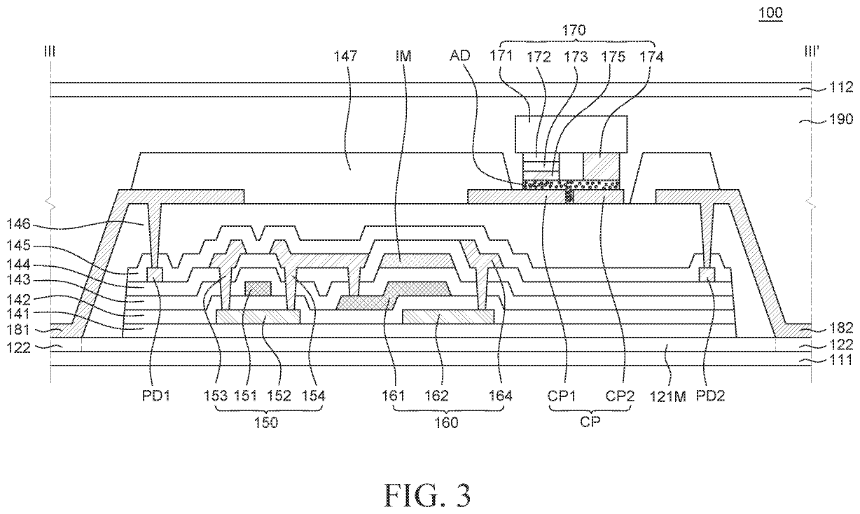

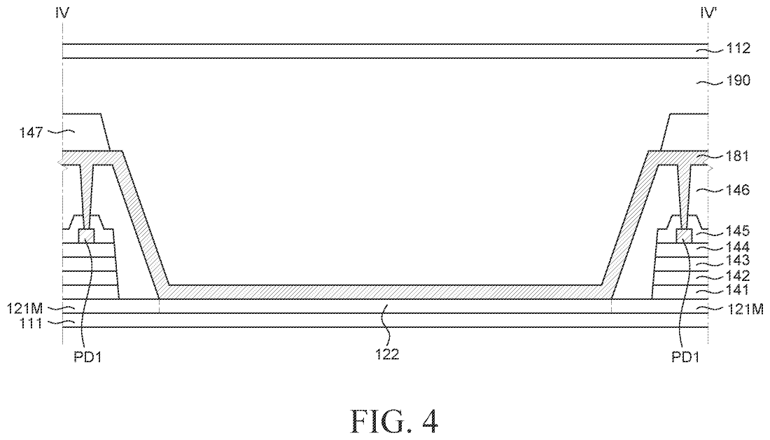

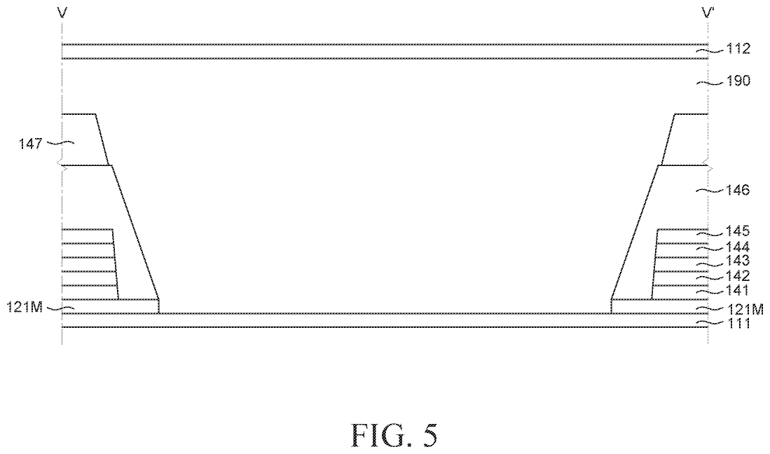

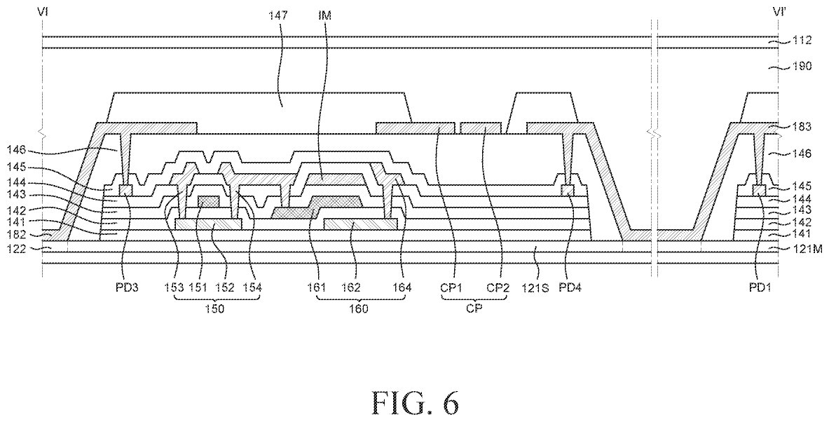

FIG. 1 is a plan view of a display device according to an exemplary embodiment of the present disclosure. FIG. 2 is an enlarged plan view of an active area of the display device according to an exemplary embodiment of the present disclosure. FIG. 3 is a cross-sectional view taken along of III-III′ FIG. 2 according to an exemplary embodiment of the present disclosure. FIG. 4 is a cross-sectional view taken along IV-IV′ of FIG. 2 according to an exemplary embodiment of the present disclosure. FIG. 5 is a cross-sectional view taken along V-V′ of FIG. 2 according to an exemplary embodiment of the present disclosure. FIG. 6 is a cross-sectional view taken along VI-VI′ of FIG. 2 according to an exemplary embodiment of the present disclosure. In FIG. 1, for convenience of description, illustrations of sub-plate patterns 121S of first plate patterns 121 are omitted, and main plate patterns 121M thereof are illustrated.

First, a display device 100 according to an exemplary embodiment of the present disclosure is a display device capable of displaying an image even if it is bent or stretched, and may also be referred to a stretchable display device or a flexible display device. The display device 100 may have higher flexibility and stretchability than conventional, typical display devices. Accordingly, a user can bend or stretch the display device 100, and a shape of the display device 100 can be freely changed according to the user's manipulation. For example, when the user grabs and pulls an end of the display device 100, the display device 100 may be stretched in a pulling direction by the user. If the user places the display device 100 on an uneven outer surface, the display device 100 can be disposed to be bent according to a shape of the outer surface. When force applied by the user is removed, the display device 100 can return to an original shape thereof.

Referring to FIGS. 1 to 3 together, a lower substrate 111 is a substrate for supporting and protecting various components of the display device 100. In addition, the lower substrate 111 may support a pattern layer 120 on which pixels PX, gate drivers GD, and power supplies PS are formed. In addition, an upper substrate 112 is a substrate for covering and protecting various components of the display device 100. The upper substrate 112 may cover the pixels PX, the gate drivers GD, and the power supplies PS.

Each of the lower substrate 111 and the upper substrate 112 is a ductile substrate and may be formed of an insulating material that can be bent or stretched. For example, each of the lower substrate 111 and the upper substrate 112 may be formed of silicone rubber such as polydimethylsiloxane (PDMS) or elastomers such as polyurethane (PU) and polytetrafluoroethylene (PTFE), and thus, may have flexible properties. Materials of the lower substrate 111 and the upper substrate 112 may be the same, but are not limited thereto and may be variously modified.

Each of the lower substrate 111 and the upper substrate 112 is a ductile substrate and may be reversibly expandable and contractible. Accordingly, the lower substrate 111 may be referred to as a lower stretchable substrate, a lower flexible substrate, a lower extendable substrate, a lower ductile substrate, a first stretchable substrate, a first flexible substrate, a first extendable substrate, or a first ductile substrate. The upper substrate 112 may be referred to as an upper stretchable substrate, an upper flexible substrate, an upper extendable substrate, an upper ductile substrate, a second stretchable substrate, a second flexible substrate, a second extendable substrate, or a second ductile substrate. Moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a point in time at which an object stretched is broken or cracked. A thickness of the lower substrate may be 10 μm to 1 mm, but is not limited thereto.

Referring to FIG. 1, the lower substrate 111 may have an active area AA and a non-active area NA surrounding the active area AA. However, the active area AA and the non-active area NA are not limited only to the lower substrate 111 and may be referred throughout the display device 100.

The active area AA is an area in which an image is displayed on the display device 100. A plurality of the pixels PX are disposed in the active area AA. Each of the plurality of the pixels PX may include a display element and various driving elements for driving the display element. The various driving elements may include at least one thin film transistor TFT and a capacitor, but the present disclosure is not limited thereto. Each of the plurality of pixels PX may be connected to various lines. For example, each of the plurality of pixels PX may be connected to various lines such as scan lines, data lines, reference lines, emission control lines, high potential power lines, and low potential power lines.

The non-active area NA is an area in which an image is not displayed. The non-active area NA may be an area disposed adjacent to the active area AA. For example, the non-active area NA may be an area surrounding the active area AA. However, the present disclosure is not limited thereto, and the non-active area NA corresponds to an area of the lower substrate 111 excluding the active area AA and may be changed and separated into various shapes. Components for driving the plurality of pixels PX disposed in the active area AA, for example, the gate drivers GD and the power supplies PS may be disposed in the non-active area NA. In addition, a plurality of pads that are connected to the gate drivers GD and the data drivers DD may be disposed in the non-active area NA, and each of the pads may be connected to the plurality of pixels PX in the active area AA.

The pattern layer 120 is disposed on the lower substrate 111. The pattern layer 120 includes a plurality of first plate patterns 121 and a plurality of first line patterns 122 that are disposed in the active area AA and a plurality of second plate patterns 123 and a plurality of second line patterns 124 that are disposed in the non-active area NA.

The plurality of first plate patterns 121 may be disposed in the active area AA of the lower substrate 111. The plurality of second plate patterns 123 may be disposed in the non-active area NA of the lower substrate 111. The plurality of first plate patterns 121 and the plurality of second plate patterns 123 may be disposed in the form of islands that are spaced apart from each other. Each of the plurality of first plate patterns 121 and the plurality of second plate patterns 123 may be individually separated. Accordingly, the plurality of first plate patterns 121 and the plurality of second plate patterns 123 may be referred to as first island patterns and second island patterns, or first individual patterns and second individual patterns.

Referring to FIG. 1, a size of each of the plurality of second plate patterns 123 may be greater than a size of each of the plurality of first plate patterns 121. One stage of the gate driver GD may be disposed on each of the plurality of second plate patterns 123. Accordingly, since an area that is occupied by various circuit components constituting one stage of the gate driver GD is relatively greater than an area occupied by one pixel PX, the size of each of the plurality of second plate patterns 123 may be greater than the size of each of the first plate patterns 121.

Meanwhile, it is illustrated in FIG. 1 that the plurality of second plate patterns 123 are disposed in the non-active area NA on both sides of the active area AA in an X direction, but the illustration of FIG. 1 is exemplary. The plurality of second plate patterns 123 may be disposed in any area of the non-active area NA. In addition, although the plurality of first plate patterns 121 and the plurality of second plate patterns 123 are illustrated in quadrangular shapes, the present disclosure is not limited thereto. The plurality of first plate patterns 121 and the plurality of second plate patterns 123 may be changeable in various shapes.

Referring to FIGS. 1 and 2, the plurality of first line patterns 122 of the pattern layer 120 are disposed in the active area AA. The plurality of first line patterns 122 are patterns that connect the first plate patterns 121 adjacent to each other, and may be referred to as internal connection patterns. That is, the plurality of first line patterns 122 are disposed between the plurality of first plate patterns 121.

The plurality of second line patterns 124 of the pattern layer 120 are disposed in the non-active area NA. The plurality of second line patterns 124 are patterns that connect the first plate patterns 121 and the second plate patterns 123 adjacent to each other or connect the plurality of second plate patterns 123 adjacent to each other. Accordingly, the plurality of second line patterns 124 may be referred to as external connection patterns. The plurality of second line patterns 124 may be disposed between the first plate patterns 121 and the second plate patterns 123 that are adjacent to each other, and disposed between the plurality of second plate patterns 123 that are adjacent to each other.

The plurality of first line patterns 122 and the plurality of second line patterns 124 have wavy shapes. For example, the plurality of first line patterns 122 and the plurality of second line patterns 124 may have sine wave shapes. However, the shapes of the plurality of first line patterns 122 and the plurality of second line patterns 124 are not limited thereto. For example, the plurality of first line patterns 122 and the plurality of second line patterns 124 may extend in zigzag manners. Alternatively, the plurality of first line patterns 122 and the plurality of the second line patterns 124 may have shapes, such as shapes in which a plurality of rhombus-shaped substrates are extended by being connected at vertices thereof, or may have various shapes such as shapes in which semi-circular and quadrant substrates are connected to each other. In addition, the numbers and shapes of the plurality of first line patterns 122 and the plurality of second line patterns 124 illustrated in FIG. 1 are exemplary, and the numbers and shapes of the plurality of first line patterns 122 and the plurality of second line patterns 124 may be variously changed according to design.

Meanwhile, the plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may have rigid properties compared to the lower substrate 111 and the upper substrate 112.

The plurality of first plate patterns 121, the plurality of first line patterns 122, the plurality of second plate patterns 123, and the plurality of second line patterns 124 that are rigid substrates may be formed of a plastic material having flexibility lower than that of the lower substrate 111 and the upper substrate 112. For example, the plurality of first plate patterns 121, the plurality of first line patterns 122, the plurality of second plate patterns 123, and the plurality of second line patterns 124 may be formed of at least one material among polyimide (PI), polyacrylate, and polyacetate. In this case, the plurality of first plate patterns 121, the plurality of first line patterns 122, the plurality of second plate patterns 123, and the plurality of second line patterns 124 may be formed of the same material, but the present disclosure is not limited thereto. The plurality of first plate patterns 121, the plurality of first line patterns 122, the plurality of second plate patterns 123, and the plurality of second line patterns 124 may be formed of different materials. When the plurality of first plate patterns 121, the plurality of first line patterns 122, the plurality of second plate patterns 123, and the plurality of second line patterns 124 are formed of the same material, they may be integrally formed.

In this case, moduli of elasticity of the plurality of first plate patterns 121, the plurality of first line patterns 122, the plurality of second plate patterns 123, and the plurality of second line patterns 124 may be higher than the modulus of elasticity of the lower substrate 111. The modulus of elasticity is a parameter representing a rate of deformation against a stress applied to the substrate. When the modulus of elasticity is relatively high, hardness may be relatively high. Accordingly, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. The moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but the present disclosure is not limited thereto.

Meanwhile, in some embodiments, the lower substrate 111 may be defined as including a plurality of first lower patterns and a second lower pattern. The plurality of first lower patterns may be areas of the lower substrate 111 that overlap the plurality of first plate patterns 121 and the plurality of second plate patterns 123. The second lower pattern may be a remaining area that does not overlap the plurality of first plate patterns 121 and the plurality of second plate patterns 123.

Also, the upper substrate 112 may be defined as including a plurality of first upper patterns and a second upper pattern. The plurality of first upper patterns may be areas of the upper substrate 112 that overlap the plurality of first plate patterns 121 and the plurality of second plate patterns 123. The second upper pattern may be a remaining area that does not overlap the plurality of first plate patterns 121 and the plurality of second plate patterns 123.

In this case, moduli of elasticity of the plurality of first lower patterns and first upper patterns may be higher than moduli of elasticity of the second lower pattern and the second upper pattern. For example, the plurality of first lower patterns and the first upper patterns may be formed of the same material as the plurality of first plate patterns 121 and the plurality of second plate patterns 123. The second lower pattern and the second upper pattern may be formed of a material having a modulus of elasticity lower than those of the plurality of first plate patterns 121 and the plurality of second plate patterns 123.

For example, the first lower patterns and the first upper patterns may be formed of polyimide (PI), polyacrylate, polyacetate, or the like. The second lower pattern and the second upper pattern may be formed of silicon rubber such as polydimethylsiloxane (PDMS) or an elastomer such as polyurethane (PU) or polytetrafluoroethylene (PTFE).

The gate drivers GD may be mounted on the plurality of second plate patterns 123. The gate drivers GD may be formed on the plurality of second plate patterns 123 in a gate in panel (GIP) method when various components on the plurality of first plate patterns 121 are manufactured. Accordingly, various circuit components constituting the gate drivers GD such as transistors, capacitors, and lines may be disposed on the plurality of second plate patterns 123. One stage that constitutes the gate driver GD and that is a circuit including a transistor, a capacitor, and the like, may be disposed above each of the plurality of second plate patterns 123. However, the gate driver GD may be mounted in a chip on film (COF) method, but the present disclosure is not limited thereto.

The power supplies PS are disposed on the plurality of second plate patterns 123. The power supplies PS may be formed on the second plate patterns 123 adjacent to the gate drivers GD. The power supplies PS are a plurality of power blocks patterned when manufacturing various components on the first plate patterns 121 and may be formed on the second plate patterns 123. The power supplies PS may be electrically connected to the gate drivers GD of the non-active area NA and the plurality of pixels PX of the active area AA to supply a driving voltage. Specifically, the power supplies PS may be connected to the gate drivers GD formed on the second plate patterns 123 and the plurality of pixels PX formed on the first plate patterns 121 through the second line patterns 124 and the first line patterns 122. For example, the power supplies PS may supply a gate driving voltage and a clock signal to the gate drivers GD. Also, the power supply PS may supply a power voltage to each of the plurality of pixels PX.

A printed circuit board PCB is connected to an edge of the lower substrate 111. The printed circuit board PCB is a component that transfers signals and voltages for driving display elements from control units to the display elements. Accordingly, the printed circuit board PCB may also be referred to as a driving board. The control units such as integrated circuit (IC) chips and circuit units may be mounted on the printed circuit board PCB. In addition, a memory, a processor, and the like may be mounted on the printed circuit board PCB. Also, the printed circuit board PCB provided in the display device 100 may include a stretchable area and a non-stretchable area in order to secure stretchability. An IC chip, a circuit unit, a memory, a processor and the like may also be mounted in the non-stretchable area, and lines electrically connected to the IC chip, the circuit unit, the memory, and the processor may be disposed in the stretchable area.

The data driver DD is a component which supplies a data voltage to the plurality of pixels PX disposed in the active area AA. The data driver DD may be configured in a form of an IC chip and thus, may also be referred to as a data integrated circuit D-IC. Further, the data driver DD may be mounted on the non-stretchable area of the printed circuit board PCB. That is, the data driver DD may be mounted on the printed circuit board PCB in a form of a chip on board (COB). Although in FIG. 1, it is illustrated that the data driver DD is mounted in a chip on board (COB) manner, the data driver DD may be mounted in a method such as a chip on film (COF) method, a chip on glass (COG) method, a tape carrier package (TCP) method, or the like, and the present disclosure is not limited thereto.

Also, although it is illustrated in FIG. 1 that one data driver DD is disposed to correspond to each of a plurality of columns configured by the plurality of first plate patterns 121 disposed in the active area AA, the present disclosure is not limited thereto. That is, one data driver DD may be disposed to correspond to a plurality of columns configured by the plurality of first plate patterns 121.

Referring to FIG. 2, the plurality of first plate patterns 121 disposed in the active area AA include a plurality of the main plate patterns 121M and a plurality of the sub-plate patterns 121S.

The plurality of main plate patterns 121M are substrates on which the pixels PX including a plurality of sub-pixels are disposed. The plurality of main plate patterns 121M may be disposed in a matrix form forming a plurality in rows and a plurality of columns in the active area AA.

Each of the plurality of sub-pixels is an individual unit that emits light, and a light emitting diode (LED) 170 which is a display element and a circuit for driving the LED 170 are disposed in each of the plurality of sub-pixels. The plurality of sub-pixels may include a red sub-pixel, a green sub-pixel, a blue sub-pixel, and/or a white sub-pixel, but are not limited thereto. Hereinafter, descriptions will be made on the assumption that one pixel PX including three sub-pixels is disposed on one main plate pattern 121M, but a configuration of the pixel PX is not limited thereto.

The plurality of sub-pixels include a first sub-pixel SP1, a second sub-pixel SP2, and a third sub-pixel SP3. Each of the first sub-pixel SP1, the second sub-pixel SP2, and the third sub-pixel SP3 includes the LED 170 and the pixel circuit and may independently emit light.

Meanwhile, the sub-pixels of the respective main plate patterns 121M may be disposed in various orders. On one part of the main plate patterns 121M, the plurality of sub-pixels are disposed in an order of the first sub-pixel SP1, the second sub-pixel SP2, and the third sub-pixel SP3. On another part of the main plate patterns 121M, the plurality of sub-pixels are disposed in an order of the second sub-pixel SP2, the third sub-pixel SP3, and the first sub-pixel SP1. On the other part of the main plate pattern 121M, the plurality of sub-pixels are disposed in an order of the third sub-pixel SP3, the first sub-pixel SP1, and the second sub-pixel SP2.

For example, in the main plate pattern 121M in row A and column A, the plurality of sub-pixels are disposed in the order of the first sub-pixel SP1, the second sub-pixel SP2, and the third sub-pixel SP3. In the main plate pattern 121M in row A and column C, the plurality of sub-pixels may be disposed in the order of the second sub-pixel SP2, the third sub-pixel SP3, and the first sub-pixel SP1. Further, in the main plate pattern 121M in row A and column E, the plurality of sub-pixels may be disposed in the order of the third sub-pixel SP3, the first sub-pixel SP1, and the second sub-pixel SP2.

The plurality of sub-plate patterns 121S are substrates on which a plurality of additional sub-pixels SPA are disposed. The plurality of sub-plate patterns 121S may be disposed alternately with the plurality of main plate patterns 121M between the plurality of respective main plate patterns 121M. The plurality of sub-plate patterns 121S may be disposed between a plurality in rows in which the plurality of main plate patterns 121M are disposed. Further, the plurality of sub-plate patterns 121S may be disposed between a plurality of columns in which the plurality of main plate patterns 121M are disposed. Each of the plurality of sub-plate patterns 121S may be disposed in a diagonal direction of the main plate pattern 121M. For example, the plurality of main plate patterns 121M may be disposed in row A, row C and row E and the plurality of sub-plate patterns 121S may be disposed in row B and row D. In addition, the plurality of main plate patterns 121M may be disposed in column A, column C and column E and the plurality of sub-plate patterns 121S may be disposed in column B and column D.

A size of the sub-plate pattern 121S may be smaller than that of the main plate pattern 121M. Although only one additional sub-pixel SPA is disposed in the sub-plate pattern 121S, the plurality of sub-pixels are disposed in the main plate pattern 121M and accordingly, the size of the main plate pattern 121M may be larger than that of the sub-plate pattern 121S.

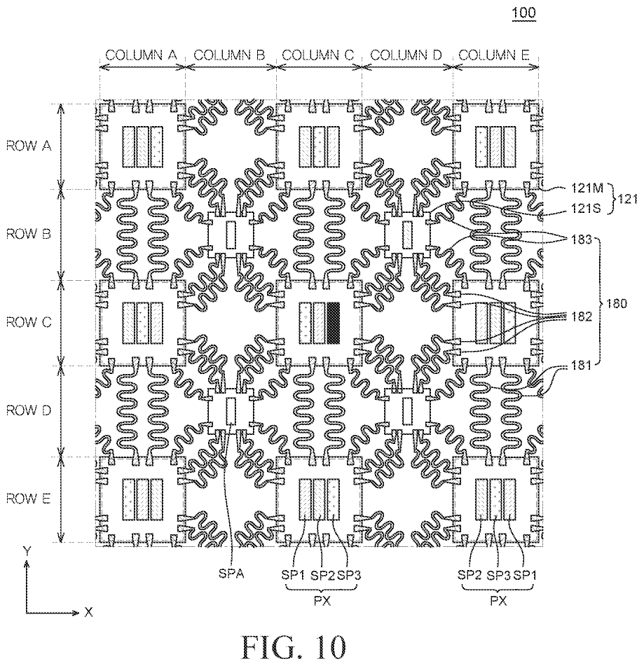

The additional sub-pixels SPA are components for compensating defects in the plurality of sub-pixels. When a defect occurs in one of the plurality of sub-pixels, the defect in the sub-pixel may be compensated for by transferring the LED 170 to the plurality of additional sub-pixels SPA. That is, the plurality of additional sub-pixels SPA may be additionally disposed to repair defects when the defects occur in the plurality of sub-pixels. The additional sub-pixel SPA may function as one of the first sub-pixel SP1, the second sub-pixel SP2, and the third sub-pixel SP3. Depending on whether the plurality of sub-pixels are defective or not, the LED 170 may be disposed or may not be disposed in the additional sub-pixel SPA. A repair method using the plurality of additional sub-pixels SPA will be described later with reference to FIGS. 10 to 13.

Hereinafter, a cross-sectional structure of the active area AA will be described in detail with reference to FIGS. 3 to 6.

Referring to FIGS. 3 and 6, a plurality of inorganic insulating layers are disposed on the plurality of first plate patterns 121 including the main plate patterns 121M and the sub-plate patterns 121S. For example, the plurality of inorganic insulating layers may include a buffer layer 141, a gate insulating layer 142, a first interlayer insulating layer 143, a second interlayer insulating layer 144, and a passivation layer 145, but are not limited thereto. For example, on the plurality of first plate patterns 121, various inorganic insulating layers may be additionally disposed, or one or more of the buffer layer 141, the gate insulating layer 142, the first interlayer insulating layer 143, the second interlayer insulating layer 144, and the passivation layer 145 may be omitted.

Specifically, the buffer layer 141 is disposed on the plurality of first plate patterns 121. The buffer layer 141 is formed on the plurality of the first plate patterns 121 to protect various components of the display device 100 from permeation of moisture (H₂O) and oxygen (O₂) from the outside of the lower substrate 111 and the plurality of first plate patterns 121. The buffer layer 141 may be formed of an insulating material. For example, the buffer layer 141 may be formed of a single layer or multilayers formed of at least one of silicon nitride (SiNx), silicon oxide (SiOx), and silicon oxynitride (SiON). However, the buffer layer 141 may be omitted depending on a structure or characteristics of the display device 100.

In this case, the buffer layer 141 may be formed only in areas overlapping with the plurality of first plate patterns 121 and the plurality of second plate patterns 123. As described above, since the buffer layer 141 may be formed of an inorganic material, it may be easily cracked, while the display device 100 is stretched. Accordingly, the buffer layer 141 may not be formed in areas between the plurality of first plate patterns 121 and the plurality of second plate patterns 123. The buffer layer 141 may be patterned in shapes of the plurality of first plate patterns 121 and the plurality of second plate patterns 123. Therefore, the buffer layer 141 may be formed only on upper portions of the plurality of first plate patterns 121 and the plurality of second plate patterns 123. Accordingly, in the display device 100 according to an exemplary embodiment of the present disclosure, the buffer layer 141 is formed only in the area where the buffer layer 141 overlaps the plurality of first plate patterns 121 and the plurality of second plate patterns 123 which are rigid substrates, so that damage to various components of the display device 100 may be prevented even when the display device 100 is deformed, such as being bent or stretched.

Referring to FIGS. 3 and 6, a switching transistor 150 and a driving transistor 160 are disposed on the buffer layer 141.

First, an active layer 152 of the switching transistor 150 and an active layer 162 of the driving transistor 160 are disposed on the buffer layer 141. For example, each of the active layer 152 of the switching transistor 150 and the active layer 162 of the driving transistor 160 may be formed of an oxide semiconductor, amorphous silicon (a-Si), or polycrystalline silicon (poly-Si), or an organic semiconductor.

The gate insulating layer 142 is disposed on the active layer 152 of the switching transistor 150 and the active layer 162 of the driving transistor 160. The gate insulating layer 142 serves to insulate a gate electrode 151 of the switching transistor 150 from the active layer 152 of the switching transistor 150, and insulate a gate electrode 161 of the driving transistor 160 and the active layer 162 of the driving transistor 160. The gate insulating layer 142 may be formed of an insulating material, for example, a single layer of inorganic silicon nitride (SiNx) or silicon oxide (SiOx) or multiple layers of silicon nitride (SiNx) or silicon oxide (SiOx). However, the present disclosure is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed on the gate insulating layer 142 to be spaced apart from each other. Further, the gate electrode 151 of the switching transistor 150 overlaps the active layer 152 of the switching transistor 150, and the gate electrode 161 of the driving transistor 160 overlaps the active layer 162 of the driving transistor 160. Each of the gate electrode 151 of the switching transistor 150 and the gate electrode 161 of the driving transistor 160 may be formed of any one of various metallic materials, for example, any one of molybdenum (Mo), aluminum (Al), chromium (Cr), gold (Au), titanium (Ti), nickel (Ni), neodymium (Nd) and copper (Cu). Alternatively, each of the gate electrode 151 of the switching transistor 150 and the gate electrode 161 of the driving transistor 160 may be formed of an alloy of two or more of the metallic materials, or multiple layers thereof. However, the present disclosure is not limited thereto.

The first interlayer insulating layer 143 is disposed on the gate electrode 151 of the switching transistor 150 and the gate electrode 161 of the driving transistor 160. The first interlayer insulating layer 143 insulates the gate electrode 161 of the driving transistor 160 from an intermediate metal layer IM. The first interlayer insulating layer 143 may be formed of an inorganic material like the buffer layer 141. For example, the first interlayer insulating layer 143 may be formed as a single layer of silicon nitride (SiNx) or silicon oxide (SiOx) or multiple layers of silicon nitride (SiNx) or silicon oxide (SiOx), but is not limited thereto.

The intermediate metal layer IM overlapping the gate electrode 161 of the driving transistor 160 is disposed on the first interlayer insulating layer 143. A storage capacitor may be formed in an overlapping area between the intermediate metal layer IM and the gate electrode 161 of the driving transistor 160. Specifically, the gate electrode 161 of the driving transistor 160 and the intermediate metal layer IM are disposed to correspond to each other with the first interlayer insulating layer 143 interposed therebetween to form a storage capacitor. However, the intermediate metal layer IM may overlap another electrode other than the gate electrode 161 to form a storage capacitor, but is not limited thereto.

The intermediate metal layer IM may be formed of any one of various metallic materials, for example, any one of molybdenum (Mo), aluminum (Al), chromium (Cr), gold (Au), titanium (Ti), nickel (Ni), neodymium (Nd) and copper (Cu). Alternatively, the intermediate metal layer IM may be formed of an alloy of two or more of the metallic materials, or multiple layers thereof. However, the present disclosure is not limited thereto.

The second interlayer insulating layer 144 is disposed on the intermediate metal layer IM. The second interlayer insulating layer 144 insulates the gate electrode 151 of the switching transistor 150 from a source electrode 153 and a drain electrode 154 of the switching transistor 150. Also, the second interlayer insulating layer 144 insulates the intermediate metal layer IM from a source electrode and a drain electrode 164 of the driving transistor 160. The second interlayer insulating layer 144 may also be formed of an inorganic material like the buffer layer 141. For example, the second interlayer insulating layer 144 may be formed as a single layer of silicon nitride (SiNx) or silicon oxide (SiOx) or multiple layers of silicon nitride (SiNx) or silicon oxide (SiOx), but is not limited thereto.

The source electrode 153 and the drain electrode 154 of the switching transistor 150 are disposed on the second interlayer insulating layer 144. Also, the source electrode and the drain electrode 164 of the driving transistor 160 are disposed on the second interlayer insulating layer 144. The source electrode 153 and the drain electrode 154 of the switching transistor 150 are disposed on the same layer to be spaced apart from each other. Further, although the source electrode of the driving transistor 160 is omitted in FIGS. 3 and 6, the source electrode of the driving transistor 160 may also be disposed on the same layer as the drain electrode 164 of the driving transistor 160 to be spaced apart therefrom. In the switching transistor 150, the source electrode 153 and the drain electrode 154 may be electrically connected to the active layer 152 in a manner in which they come in contact with the active layer 152. In the driving transistor 160, the source electrode and the drain electrode 164 may be electrically connected to the active layer 162 in a manner in which they come in contact with the active layer 162. Also, the drain electrode 154 of the switching transistor 150 may be electrically connected to the gate electrode 161 of the driving transistor 160 in a manner in which it comes in contact with the gate electrode 161 of the driving transistor 160 through a contact hole.

The source electrode 153 and the drain electrode 154 of the switching transistor 150 and the source electrode and the drain electrode 164 of the driving transistor 160 may be formed of any one of various metallic materials, for example, any one of molybdenum (Mo), aluminum (Al), chromium (Cr), gold (Au), titanium (Ti), nickel (Ni), neodymium (Nd) and copper (Cu). Alternatively, the source electrode 153 and the drain electrode 154 of the switching transistor 150 and the source electrode and the drain electrode 164 of the driving transistor 160 may be formed of an alloy of two or more of the metallic materials, or multiple layers thereof. However, the present disclosure is not limited thereto.

Meanwhile, in the present disclosure, the switching transistor 150 and the driving transistor 160 are described as having a coplanar structure, but various transistors such as a staggered structure may also be used. Also, in the present disclosure, the switching transistor 150 and the driving transistor 160 may be formed in a bottom gate structure instead of a top gate structure, but are not limited thereto.

Referring to FIGS. 3 and 4, first pads PD1 and second pads PD2 are disposed on the second interlayer insulating layer 144 of the main plate patterns 121M.

A plurality of the first pads PD1 are pads connecting first connection lines 181 and lines on the main plate patterns 121M, and third connection lines 183 and lines on the main plate patterns 121M. The lines disposed on the main plate patterns 121M may be electrically connected to the first connection lines 181 and the third connection lines 183 through the first pads PD1. The first pads PD1 may be disposed adjacent to upper edges and lower edges of the main plate patterns 121M. The plurality of first pads PD1 may be electrically connected to the first connection lines 181 and the third connection lines 183 through contact holes formed in a planarization layer 146 and the passivation layer 145. The first connection lines 181 may transmit signals to the lines disposed on the main plate patterns 121M, for example, some data lines among the plurality of data lines, through the first pads PD1. The third connection lines 183 may transmit signals to the lines disposed on the main plate patterns 121M, for example, to each of remaining data lines among the plurality of data lines and reference lines, through the first pads PD1. For example, a data voltage supplied from the first connection line 181 to the first pad PD1 and the data line may be transferred to the switching transistor 150. For example, a data voltage supplied from the third connection line 183 to the first pad PD1 and the data line may be transferred to the switching transistor 150.

The second pads PD2 are pads connecting the second connection lines 182 and lines on the main plate patterns 121M. The lines disposed on the main plate patterns 121M and the second connection lines 182 may be electrically connected through the second pads PD2. The second pads PD2 may be disposed adjacent to left edges and right edges of the main plate patterns 121M. The second pads PD2 may be electrically connected to the second connection lines 182 through contact holes formed in the planarization layer 146 and the passivation layer 145. The second connection lines 182 may transmit signals to the lines disposed on the main plate patterns 121M, such as scan line, emission control lines, high potential power lines, and low potential power lines, respectively, through the second pads PD2. For example, a scan signal supplied from the second connection line 182 to the second pad PD2 and the scan line may be transferred to the gate electrode 151 of the switching transistor 150. For example, a low potential power voltage transferred from the second connection line 182 to the second pad PD2 and the low potential power line may be transferred to an n-electrode 174 of the LED 170.

Referring to FIG. 6, third pads PD3 and fourth pads PD4 are disposed on the second interlayer insulating layer 144 of the sub-plate patterns 121S.

The third pads PD3 are pads connecting the second connection lines 182 and lines on the sub-plate patterns 121S. The lines disposed on the sub-plate patterns 121S and the second connection lines 182 may be electrically connected through the third pads PD3. The third pads PD3 may be disposed adjacent to upper edges and lower edges of the sub-plate patterns 121S. The third pads PD3 may be electrically connected to the second connection lines 182 through contact holes formed in the planarization layer 146 and the passivation layer 145. The second connection lines 182 may transmit signals to the lines disposed on the sub-plate patterns 121S, such as scan line, emission control lines, high potential power lines, and low potential power lines, respectively, through the third pads PD3. For example, scan signals supplied from the plurality of second connection lines 182 to the third pads PD3 and the scan lines may be transferred to the gate electrode 151 of the switching transistor 150.

The fourth pads PD4 are pads connecting the third connection lines 183 and lines on the sub-plate patterns 121S. The lines disposed on the sub-plate patterns 121S and the third connection lines 183 may be electrically connected through the fourth pads PD4. The fourth pads PD4 may be disposed adjacent to left edges and right edges of the sub-plate patterns 121S. The fourth pads PD4 may be electrically connected to the third connection lines 183 through contact holes formed in the planarization layer 146 and the passivation layer 145. The third connection lines 183 may transmit signals to the lines disposed on the sub-plate pattern 121S, such as data lines and reference lines, respectively, through the fourth pads PD4. For example, a data voltage supplied from the third connection line 183 to the fourth pad PD4 and the data line may be transferred to the switching transistor 150.

The first pads PD1, the second pads PD2, the third pads PD3, and the fourth pads PD4 may be formed of the same material as the source electrode 153 and the drain electrodes 154 and 164, but the present disclosure is not limited thereto.

Referring to FIGS. 3 and 6, the passivation layer 145 is formed on the switching transistor 150 and the driving transistor 160 of the main plate pattern 121M and the sub-plate pattern 121S. The passivation layer 145 may cover the switching transistor 150 and the driving transistor 160 to protect the switching transistor 150 and the driving transistor 160 from permeation of moisture and oxygen. The passivation layer 145 may be formed of an inorganic material and may be formed as a single layer or multiple layers, but is not limited thereto.

Meanwhile, the gate insulating layer 142, the first interlayer insulating layer 143, the second interlayer insulating layer 144, and the passivation layer 145 may be patterned and formed only in areas where they overlap the plurality of first plate patterns 121. The gate insulating layer 142, the first interlayer insulating layer 143, the second interlayer insulating layer 144, and the passivation layer 145 may also be formed of an inorganic material like the buffer layer 141. The gate insulating layer 142, the first interlayer insulating layer 143, the second interlayer insulating layer 144, and the passivation layer 145 may be easily damaged, such as being easily cracked, while the display device 100 is stretched. Accordingly, the gate insulating layer 142, the first interlayer insulating layer 143, the second interlayer insulating layer 144, and the passivation layer 145 may not be formed in areas between the plurality of first plate patterns 121. The gate insulating layer 142, the first interlayer insulating layer 143, the second interlayer insulating layer 144, and the passivation layer 145 may be patterned in the shapes of the plurality of first plate patterns 121 and formed only on the upper portions of the plurality of first plate patterns 121.

The planarization layer 146 is formed on the passivation layer 145. The planarization layer 146 planarizes upper portions of the switching transistor 150 and the driving transistor 160. The planarization layer 146 may be formed as a single layer or a plurality of layers and may be formed of an organic material. Thus, the planarization layer 146 may also be referred to as an organic insulating layer. For example, the planarization layer 146 may be formed of an acrylic-based organic material, but is not limited thereto.

Referring to FIGS. 3 and 6, the planarization layer 146 may be disposed on the plurality of first plate patterns 121 to cover upper surfaces and side surfaces of the buffer layer 141, the gate insulating layer 142, the first interlayer insulating layer 143, the second interlayer insulating layer 144, and the passivation layer 145. The planarization layer 146 surrounds the buffer layer 141, the gate insulating layer 142, the first interlayer insulating layer 143, the second interlayer insulating layer 144, and the passivation layer 145 together with the plurality of first plate patterns 121. Specifically, the planarization layer 146 may be disposed to cover an upper surface and a side surface of the passivation layer 145, a side surface of the first interlayer insulating layer 143, a side surface of the second interlayer insulating layer 144, a side surface of the gate insulating layer 142, a side surface of the buffer layer 141 and a part of upper surfaces of the plurality of first plate patterns 121.

An incline angle of the side surface of the planarization layer 146 may be less than those of the side surfaces of the buffer layer 141, the gate insulating layer 142, the first interlayer insulating layer 143, the second interlayer insulating layer 144 and the passivation layer 145. For example, the side surface of the planarization layer 146 may have an incline that is less than an incline of the side surface of the passivation layer 145, the side surface of the first interlayer insulating layer 143, the side surface of the second interlayer insulating layer 144, the side surface of the gate insulating layer 142 and the side surface of the buffer layer 141. Thus, the planarization layer 146 may compensate for steps between the side surfaces of the buffer layer 141, the gate insulating layer 142, the first interlayer insulating layer 143, the second interlayer insulating layer 144, and the passivation layer 145. Accordingly, the connection lines 180 in contact with the side surfaces of the planarization layer 146 are disposed to have a gentle incline. Therefore, when the display device 100 is stretched, stress generated in the connection lines 180 may be reduced. In addition, since the side surface of the planarization layer 146 has a relatively gentle incline, cracking of the connection lines 180 or separation of the connection lines 180 from the side surfaces of the planarization layer 146 may be suppressed.

Meanwhile, in a general display device, various lines such as a plurality of scan lines and a plurality of data lines are extended in linear shapes and are disposed between a plurality of sub-pixels, and the plurality of sub-pixels are connected to a single line. Therefore, in the general display device, various lines such as gate lines, data lines, high potential voltage lines and reference lines are continuously extended on a substrate.

Unlike this, in the display device 100 according to an exemplary embodiment of the present disclosure, various lines such as scan lines, data lines, high potential power lines, reference lines, and the like formed in linear shapes, which can be considered to be used in a general display device, are disposed only on the plurality of first plate patterns 121 and the plurality of second plate patterns 123. That is, in the display device 100 according to an exemplary embodiment of the present disclosure, lines formed in linear shapes are disposed only on the plurality of first plate patterns 121 and the plurality of second plate patterns 123.

In the display device 100 according to an exemplary embodiment of the present disclosure, the pads on two first plate patterns 121 adjacent to each other may be connected by the connection lines 180. Therefore, various lines on the two adjacent first plate patterns 121 may be electrically connected to each other through the pads and the connection lines 180. Therefore, the display device 100 according to an exemplary embodiment of the present disclosure may include the plurality of connection lines 180 to electrically connect various lines, such as scan lines, data lines, high potential power lines, reference lines, and the like, between the plurality of first plate patterns 121. For example, data lines may be disposed on the plurality of main plate patterns 121M disposed adjacent to each other in a Y-axis direction, and first pads PD1 may be disposed at both ends of the data lines. In this case, each of the plurality of first pads PD1 on the plurality of main plate patterns 121M disposed adjacent to each other in the Y-axis direction may be connected to each other by the connection lines 180 functioning as data lines. Accordingly, the data lines disposed on the plurality of main plate patterns 121M and the connection lines 180 disposed on the first line patterns 122 may function as single data lines. In addition, in addition to the data lines, all of various lines that may be included in the display device 100, for example, scan lines, emission control lines, low potential power lines, high potential power lines, and reference lines, may also be electrically connected by the connection lines 180 as described above.

Specifically, the connection lines 180 are disposed on the plurality of first line patterns 122. The connection lines 180 may electrically connect the pads on the first plate patterns 121 adjacent to each other. The connection lines 180 may extend from the first line patterns 122 toward upper portions of the first plate patterns 121 to be electrically connected to the pads on the first plate patterns 121.

The plurality of connection lines 180 include a plurality of the first connection lines 181, a plurality of the second connection lines 182, and a plurality of the third connection lines 183.

The plurality of first connection lines 181 are lines extending in the Y-axis direction between the plurality of main plate patterns 121M. The plurality of first connection lines 181 are lines that electrically connect a plurality of lines disposed on the plurality of main plate patterns 121M to each other. The first connection lines 181 are disposed on the first line patterns 122 extending in the Y-axis direction between the plurality of main plate patterns 121M among the plurality of first line patterns 122. The first connection lines 181 may extend from the first line patterns 122 to upper portions of the main plate patterns 121M and be connected to the first pads PD1 on the main plate patterns 121M. The first connection lines 181 may be disposed between the main plate patterns 121M disposed in the same column, and may electrically connect some of the data lines on a pair of the main plate patterns 121M adjacent to each other. Thus, the first connection lines 181 may function as data lines.

The second connection lines 182 are lines disposed between the main plate patterns 121M and the sub-plate patterns 121S. The second connection lines 182 may extend in directions different from an X-axis direction and the Y-axis direction, for example, in inclined directions, between the main plate patterns 121M and the sub-plate patterns 121S. The second connection lines 182 are lines electrically connecting the lines disposed on the main plate patterns 121M and the lines disposed on the sub-plate patterns 121S to each other. The second connection lines 182 may be disposed on the first line patterns 122 disposed between the main plate patterns 121M and the sub-plate patterns 121S among the plurality of first line patterns 122. For example, the second connection lines 182 may be disposed on the first line patterns 122 extending from the left edges and right edges of the main plate patterns 121M to the upper edges and lower edges of the sub-plate patterns 121S. One ends of the second connection lines 182 may extend to the upper portions of the main plate patterns 121M and be connected to the second pads PD2 of the main plate patterns 121M. And the other ends of the second connection lines 182 may extend to upper portions of the sub-plate patterns 121S and be connected to the third pads PD3 of the sub-plate patterns 121S. The second connection lines 182 may electrically connect the scan lines, the emission control lines, the high potential power lines, and the low potential power lines on the main plate patterns 121M to the scan lines, the emission control lines, the high potential power lines, and the low potential power lines on the sub-plate patterns 121S, respectively. Accordingly, the second connection line 182 may function as one of the scan line, the emission control line, the high potential power line, and the low potential power line.

The third connection lines 183 are lines disposed between the main plate patterns 121M and the sub-plate patterns 121S. The third connection lines 183 may extend in directions different from the X-axis direction and the Y-axis direction, for example, in inclined directions, between the main plate patterns 121M and the sub-plate patterns 121S. The third connection lines 183 are lines electrically connecting the lines disposed on the main plate pattern 121M and the lines disposed on the sub-plate patterns 121S to each other. The third connection lines 183 may be disposed on the first line patterns 122 disposed between the main plate patterns 121M and the sub-plate patterns 121S among the plurality of first line patterns 122. For example, the third connection lines 183 may be disposed on the first line patterns 122 extending from the upper edges and lower edges of the main plate patterns 121M to the left edges and right edges of the sub-plate patterns 121S. First ends of the third connection lines 183 may extend to the upper portions of the main plate patterns 121M and be connected to the first pads PD1 of the main plate patterns 121M. And second ends of the third connection lines 183 may extend to the upper portions of the sub-plate patterns 121S and be connected to the fourth pads PD4 of the sub-plate patterns 121S. The third connection lines 183 may electrically connect the data lines and the reference lines on the main plate patterns 121M with the data lines and the reference lines on the sub-plate patterns 121S, respectively. Accordingly, the third connection lines 183 may function as the data line and the reference line.

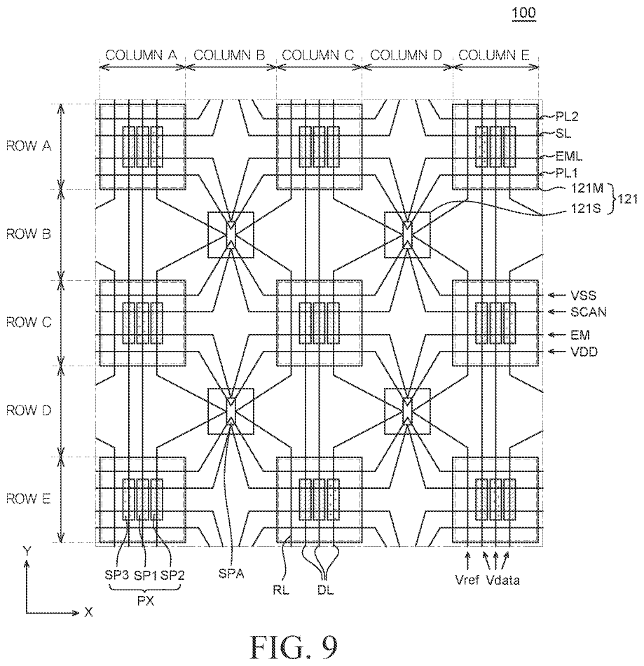

Meanwhile, the lines of the main plate patterns 121M and the lines of the sub-plate patterns 121S may be connected to each other through the second connection lines 182 and the third connection lines 183. That is, the sub-pixels of the main plate patterns 121M may share lines with the additional sub-pixels SPA of the sub-plate patterns 121S. A more detailed description of this line-sharing structure will be described later with reference to FIG. 9.

The plurality of connection lines 180 may be formed of a metal material such as copper (Cu), aluminum (Al), titanium (Ti), or molybdenum (Mo), or may be formed of a laminated structure of metal materials such as copper/molybdenum-titanium (Cu/Moti), or titanium/aluminum/titanium (Ti/Al/Ti), but the present disclosure is not limited thereto.

In addition, as illustrated in FIGS. 3 to 6, the first connection line 181 extends from an upper surface of the first line pattern 122 to the upper portion of the main plate pattern 121M, and may be disposed to be in contact with an upper surface and side surfaces of the planarization layer 146 on the main plate pattern 121M. Further, the second connection line 182 and the third connection line 183 also extend from the first line pattern 122 to the upper portion of the main plate pattern 121M and the upper portion of the sub-plate pattern 121S, and may be disposed to be in contact with the upper surface and side surfaces of the planarization layer 146 on the main plate pattern 121M and the sub-plate pattern 121S.

However, since it is unnecessary to dispose rigid patterns in an area where the plurality of connection lines 180 are not disposed, the first line patterns 122 which are rigid patterns are not disposed below the plurality of connection lines 180.

Next, referring to FIGS. 3 and 6, connection pads CP are disposed on the planarization layer 146 of the main plate pattern 121M and the sub-plate pattern 121S. The connection pads CP are pads for electrically connecting the LED 170 with the driving transistor 160 and the low potential power line. The connection pads CP includes a first connection pad CP1 and a second connection pad CP2. The drain electrode 164 of the driving transistor 160 and a p-electrode 175 of the LED 170 may be electrically connected through the first connection pad CP1, and the low potential power line and the n-electrode 174 of the LED 170 may be electrically connected through the second connection pad CP2. In this case, the second connection pad CP2 may extend from the second connection line 182 that transmits a low potential power voltage and be formed integrally with the second connection line 182. Accordingly, when the display device 100 is driven, different voltage levels applied to the first and second connection pads CP1 and CP2 are transferred to the n-electrode 174 and the p-electrode 175, respectively, so that the LED 170 emits light.

A bank 147 is disposed on the connection lines 180, the connection pads CP, and the planarization layer 146 of the main plate pattern 121M and the sub-plate pattern 121S. The bank 147 is a component that divides adjacent sub-pixels. The bank 147 is disposed to cover at least a portion of the connection pads CP, the connection lines 180 and the planarization layer 146. The bank 147 may be formed of an insulating material. Also, the bank 147 may include a black material. The bank 147 serves to cover lines visible through the active area AA by including a black material. The bank 147 may be formed of, for example, a transparent carbon-based mixture, and specifically, may include carbon black. However, the present disclosure is not limited thereto, and the bank 147 may be formed of a transparent insulating material. In addition, in FIG. 3, a thickness of the bank 147 is illustrated as being smaller than a thickness of the LED 170, but the thickness of the bank 147 may be equal to or greater than the thickness of the LED 170, but the present disclosure is not limited thereto.

Referring to FIG. 3, the LED 170 is disposed on the connection pads CP on the main plate pattern 121M. The LED 170 includes an n-type layer 171, an active layer 172, a p-type layer 173, the n-electrode 174, and the p-electrode 175. The LED 170 of the display device 100 according to an exemplary embodiment of the present disclosure has a flip-chip structure in which the n-electrode 174 and the p-electrode 175 are formed together on one surface thereof

The p-type layer 173 is disposed on the connection pad CP, and the n-type layer 171 is disposed on the p-type layer 173. The n-type layer 171 and the p-type layer 173 may be layers formed by doping a specific material with n-type impurities and p-type impurities, respectively. For example, the n-type layer 171 and the p-type layer 173 may be layers formed by doping a material such as gallium nitride (GaN), indium aluminum phosphide (InAlP), or gallium arsenide (GaAs) with n-type impurities and p-type impurities, respectively. The p-type impurity may be magnesium, zinc (Zn), or beryllium (Be), and the n-type impurity may be silicon (Si), germanium, or tin (Sn), but the present disclosure is not limited thereto.

The active layer 172 is disposed between the n-type layer 171 and the p-type layer 173. The active layer 172 is a light emitting layer that emits light from the LED 170 and may be formed of a single or multi-quantum well (MQW) structure, for example, indium gallium nitride (InGaN) or gallium nitride (GaN), but the present disclosure is not limited thereto.

As described above, the LED 170 of the display device 100 according to an exemplary embodiment of the present disclosure is manufactured by sequentially stacking the n-type layer 171, the active layer 172, and the p-type layer 173 and then, etching a predetermined portion of the layers to form the n-electrode 174 and the p-electrode 175. At this time, the predetermined portion is a space for separating the n-electrode 174 and the p-electrode 175, and the predetermined portion is etched to expose a portion of the n-type layer 171. In other words, surfaces of the LED 170 on which the n-electrode 174 and the p-electrode 175 are to be disposed may have different height levels instead of having a flatten surface.

In this manner, the n-electrode 174 may be disposed on one surface of the n-type layer 171 that is exposed in an etched area. The p-electrode 175 may be disposed on one surface of the p-type layer 173 disposed in an unetched area.

Referring to FIG. 3, an adhesive layer AD is disposed between the LED 170 of the main plate pattern 121M and the connection pads CP. The adhesive layer AD may be disposed between the n-electrode 174 and the p-electrode 175 of the LED 170 and the connection pads CP. The adhesive layer AD may be a conductive adhesive layer AD in which conductive balls are dispersed in an insulating base member. Accordingly, when heat or pressure is applied to the adhesive layer AD, the conductive balls are electrically connected in a portion of the adhesive layer AD where the heat or pressure is applied and have conductive characteristics. Also, an area of the adhesive layer AD to which pressure is not applied may have insulating properties. The n-electrode 174 and the p-electrode 175 may be electrically connected to the connection pads CP through the adhesive layer AD. For example, after applying the adhesive layer AD onto the connection pads CP in a method such as an inkjet method, the LED 170 is transferred onto the adhesive layer AD, and the connection pads CP and the p-electrode 175 and the n-electrode 174 may be electrically connected in a method in which the LED 170 is pressed and heated. However, other portions of the adhesive layer AD excluding a portion of the adhesive layer AD disposed between the n-electrode 174 and the connection pad CP and a portion of the adhesive layer AD disposed between the p-electrode 175 and the connection pad CP have insulating properties. In FIG. 3, the adhesive layers AD covering a pair of the connection pads CP are connected to each other, but the adhesive layers AD may be disposed on each of the pair of connection pads CP in a separate form.

Referring to FIG. 6, depending on whether a defect occurs in the plurality of sub-pixels on the main plate patterns 121M, the adhesive layer AD and the LED 170 may not be disposed or may be disposed on the plurality of sub-plate patterns 121S. For example, when all of the sub-pixels of the main plate pattern 121M adjacent to one sub-plate pattern 121S are normal, the adhesive layer AD and the LED 170 may not be disposed on the connection pads CP of the one sub-plate pattern 121S. Conversely, when one of the sub-pixels of the main plate pattern 121M adjacent to one sub-plate pattern 121S is defective, the adhesive layer AD and the LED 170 may be disposed on the connection pads CP of the one sub-plate pattern 121S as illustrated in FIG. 3.

Referring to FIGS. 3 and 6, the upper substrate 112 serves to support various components disposed under the upper substrate 112. Specifically, the upper substrate 112 may be formed by coating a material constituting the upper substrate 112 on the lower substrate 111 and the first plate patterns 121 and then curing the material. The upper substrate 112 may be disposed to be in contact with the lower substrate 111, the first plate patterns 121, the first line patterns 122, and the connection lines 180.

The upper substrate 112 may be formed of the same material as the lower substrate 111. For example, the upper substrate 112 may be formed of silicone rubber such as polydimethylsiloxane (PDMS) or an elastomer such as polyurethane (PU) or polytetrafluoroethylene (PTFE). Thus, the upper substrate 112 may have flexibility. However, the materials of the upper substrate 112 are not limited thereto.

Meanwhile, although not illustrated in FIG. 3, a polarizing layer may also be disposed on the upper substrate 112. The polarizing layer may serve to polarize light incident from the outside of the display device 100 and reduce reflection of external light. Further, instead of the polarizing layer, other optical films or the like may be disposed on the upper substrate 112.

In addition, the filling layer 190 may be disposed between the lower substrate 111 and the upper substrate 112. The filling layer 190 fills a gap between components disposed on the upper substrate 112 and the lower substrate 111. The filling layer 190 may be formed of a curable adhesive. Specifically, a material for forming the filling layer 190 is formed to be coated on the entire surface of the lower substrate 111 and then cured, so that the filling layer 190 may be disposed between components disposed on the upper substrate 112 and the lower substrate 111. For example, the filling layer 190 may be an optically clear adhesive (OCA), and may include an acrylic adhesive, a silicone adhesive, and a urethane adhesive.

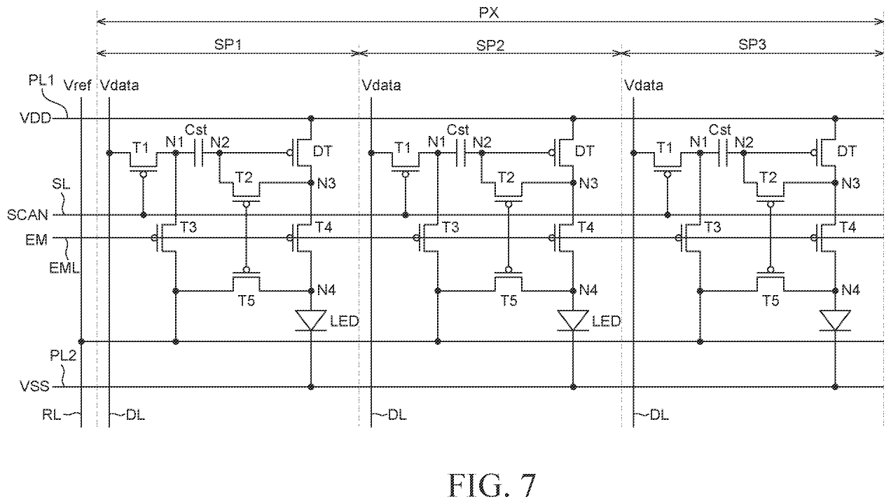

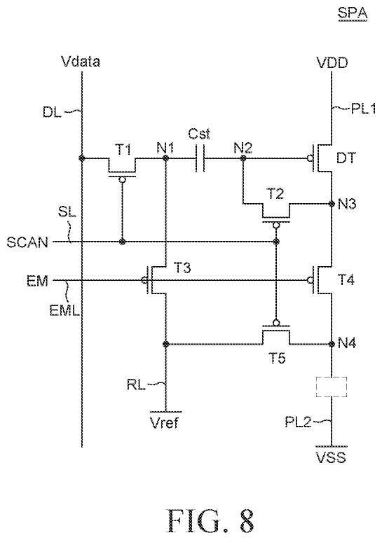

FIG. 7 is a circuit diagram of a plurality of sub-pixels of the display device according to an exemplary embodiment of the present disclosure. FIG. 8 is a circuit diagram of an additional sub-pixel of the display device according to an exemplary embodiment of the present disclosure. FIG. 9 is a diagram for explaining transmission paths of various signals in the display device according to an exemplary embodiment of the present disclosure. FIG. 7 is a circuit diagram of the plurality of sub-pixels disposed on one main plate pattern 121M, and FIG. 8 is a circuit diagram of the additional sub-pixel SPA disposed on one sub-plate pattern 121S. In FIG. 9, for convenience of explanation, only the first plate patterns 121, the pixels PX, the additional sub-pixels SPA, and transmission paths of a scan signal SCAN, a data voltage Vdata, a reference voltage Vref, an emission control signal EM, a high potential power voltage VDD and a low potential power voltage VSS are illustrated.

For reference, the switching transistor 150 illustrated in FIG. 3 may correspond to a first transistor T1 illustrated in FIG. 7, the driving transistor 160 illustrated in FIG. 3 may correspond to a driving transistor DT illustrated in FIG. 7, and the LED 170 illustrated in FIG. 3 may correspond to a light emitting element LED of FIG. 7. The switching transistor 150 illustrated in FIG. 6 may correspond to a first transistor T1 illustrated in FIG. 8, the driving transistor 160 illustrated in FIG. 6 may correspond to a driving transistor DT illustrated in FIG. 8, and optionally the LED 170 illustrated in FIG. 6 may correspond to a light emitting element LED of FIG. 8.

Referring to FIG. 7, in the display device 100 according to an exemplary embodiment of the present disclosure, each of the plurality of sub-pixels includes the light emitting element LED, and a pixel circuit including the driving transistor DT, a first transistor T1 to a fifth transistor T5, and a storage capacitor Cst.

The light emitting element LED of each of the plurality of sub-pixels emits light by driving current supplied from the driving transistor DT. An anode electrode of the light emitting element LED is connected to a fourth transistor T4 and the fifth transistor T5 and to a fourth node N4, and a cathode electrode of the light emitting element LED is connected to a low potential power line PL2 to which the low potential power voltage VSS is applied.

The driving transistor DT of each of the plurality of sub-pixels supplies driving current to the light emitting element LED according to a gate-source voltage. A source electrode of the driving transistor DT is connected to a high potential power line PL1 to which the high potential power voltage VDD is applied, a gate electrode of the driving transistor DT is connected to a second node N2, and a drain electrode of the driving transistor DT is connected to a third node N3.

The first transistor T1 of each of the plurality of sub-pixels applies the data voltage Vdata supplied from the data line DL to the first node N1. The first transistor T1 includes a source electrode connected to the data line DL, a drain electrode connected to the first node N1, and a gate electrode connected to the scan line SL transmitting the scan signal SCAN. Accordingly, the first transistor T1 applies the data voltage Vdata supplied from the data line DL to the first node N1 according to the scan signal SCAN at a low level, which is a turn-on level. That is, the first transistor T1 may be the switching transistor 150 that applies any one of a plurality of data voltages Vdata to each of the plurality of pixel (PX) circuits according to the scan signal SCAN.

A second transistor T2 of each of the plurality of sub-pixels diode-connects the gate electrode and the drain electrode of the driving transistor DT. The second transistor T2 includes a source electrode connected to the third node N3, which is the drain electrode of the driving transistor DT, a drain electrode connected to the second node N2, which is the gate electrode of the driving transistor DT, and a gate electrode connected to the scan line SL transmitting the scan signal SCAN. Accordingly, the second transistor T2 diode-connects the gate electrode and the drain electrode of the driving transistor DT in response to the scan signal SCAN at a low level, which is a turn-on level.

A third transistor T3 of each of the plurality of sub-pixels applies the reference voltage Vref to the first node N1. The third transistor T3 includes a source electrode connected to a reference line RL that transmits the reference voltage Vref, a drain electrode connected to the first node N1, and a gate electrode connected to an emission control line EML that transmits an emission signal. Accordingly, the third transistor T3 applies the reference voltage Vref to the first node N1 in response to an emission control signal EM at a low level, which is a turn-on level.

The fourth transistor T4 of each of the plurality of sub-pixels forms a current path between the driving transistor DT and the light emitting element LED. The fourth transistor T4 includes a source electrode connected to the third node N3 which is the drain electrode of the driving transistor DT, a drain electrode connected to the light emitting element LED, and a gate electrode connected to the emission control line EML that transmits an emission signal. Accordingly, the fourth transistor T4 may be an emission control transistor that forms a current path between the drain electrode of the driving transistor DT and the light emitting element LED in response to the emission signal.

The fifth transistor T5 of each of the plurality of sub-pixels applies the reference voltage Vref to the anode electrode of the light emitting element LED. The fifth transistor T5 includes a source electrode connected to the reference line RL that transmits the reference voltage Vref, a drain electrode connected to the anode electrode of the light emitting element LED, and a gate electrode connected to the scan line SL that transmits the scan signal SCAN. Accordingly, the fifth transistor T5 applies the reference voltage Vref to the anode electrode of the light emitting element LED in response to the scan signal SCAN at a low level, which is a turn-on level. The fifth transistor T5 may be an initialization transistor that applies the reference voltage Vref to the anode electrode of the light emitting element LED.

The storage capacitor Cst of each of the plurality of sub-pixels includes a first electrode connected to the first node N1 and a second electrode connected to the second node N2. That is, one electrode of the storage capacitor Cst is connected to the gate electrode of the driving transistor DT, and the other electrode of the storage capacitor Cst is connected to the drain electrode of the first transistor T1.

Referring to FIG. 8, in the display device 100 according to an exemplary embodiment of the present disclosure, the additional sub-pixel SPA includes a pixel circuit including a driving transistor DT, a first transistor T1 to a fifth transistor T5, and a storage capacitor Cst. The pixel circuit of the additional sub-pixel SPA is substantially identical to the circuits of the sub-pixels except that it selectively includes the light emitting element LED. The additional sub-pixel SPA also includes the driving transistor DT, the first transistor T1 to the fifth transistor T5, and the storage capacitor Cst, in the same manner as the sub-pixels. Further, the additional sub-pixel SPA may selectively include the light emitting element LED according to whether the sub-pixel adjacent thereto is defective or not.

If a defect occurs in a portion of the sub-pixels and the light emitting element LED is transferred to the additional sub-pixels SPA, a circuit structure illustrated in FIG. 7 may be implemented in the additional sub-pixels SPA of the sub-plate pattern 121S, and the additional sub-pixel SPA may also emit light in the same manner as other sub-pixels.

Conversely, as illustrated in FIG. 8, when the light emitting element LED is not transferred to the additional sub-pixel SPA, signals from various lines may be transferred to adjacent sub-pixels via the additional sub-pixel SPA. The additional sub-pixel SPA in which the light emitting element LED is not formed may function only as a line for transmitting signals between the sub-pixels. For example, the scan signal SCAN may be transmitted to the scan lines SL of other sub-pixels via the scan line SL of the additional sub-pixel SPA.

Specifically, referring to FIGS. 3 and 9 together, the lines of the main plate patterns 121M adjacent to each other may be connected to each other through the first connection lines 181, and the lines of the main plate patterns 121M and the lines of the sub-plate patterns 121S may be connected to each other through the second connection lines 182 and the third connection lines 183.

First, as described above, three sub-pixels are disposed on one main plate pattern 121M, and thus, three data lines DL may be disposed thereon. For example, each of the first sub-pixel SP1, the second sub-pixel SP2, and the third sub-pixel SP3 may be connected to different data lines DL.

The first connection lines 181 may connect some of the plurality of data lines DL of the main plate pattern 121M to some of the data lines DL of the main plate pattern 121M adjacent thereto in the Y-axis direction. For example, two data lines DL among the three data lines DL on the main plate patterns 121M adjacent to each other may be connected to each other through the first connection lines 181. In this case, some sub-pixels on the main plate patterns 121M disposed in the same column may share the same data lines DL through the first connection lines 181. For example, the data lines DL of the first sub-pixel SP1 in row A and column A, the second sub-pixel SP2 in row C and column A, and the third sub-pixel SP3 in row E and column A may be connected through the first connection lines 181. Therefore, the data voltage Vdata of the first sub-pixel SP1, the data voltage Vdata of the second sub-pixel SP2, and the data voltage Vdata of the third sub-pixel SP3 may be sequentially supplied to the data lines DL in column A.

One third connection line 183 among the plurality of third connection lines 183 may connect a remaining data line DL (which is not connected to the first connection line 181) among the plurality of data lines DL on the main plate pattern 121M with the data line DL on the sub-plate pattern 121S. The one third connection line 183 may connect the data lines DL of the main plate pattern 121M and the sub-plate pattern 121S disposed in a right column of a column in which the main plate pattern 121M is disposed. For example, the data lines DL of the main plate patterns 121M in column A and the data lines DL of the sub-plate patterns 121S in column B may be connected to each other through the third connection lines 183. In this case, the data lines DL of the main plate patterns 121M and the data lines DL of the sub-plate patterns 121S may form zigzag shapes together with the third connection lines 183. Accordingly, some of the sub-pixels of the main plate patterns 121M may share the data lines DL with the additional sub-pixels SPA of the sub-plate patterns 121S in columns adjacent to the main plate patterns 121M. For example, the data lines DL connected to each of the third sub-pixel SP3 in row A and column A, the first sub-pixel SP1 in row C and column A, and the second sub-pixel SP2 in row E and column A may be connected to the data line DL of the sub-plate pattern 121S through the third connection line 183.

Another third connection line 183 among the plurality of third connection lines 183 may connect the reference line RL on the main plate pattern 121M and the reference line RL on the sub-plate pattern 121S. Another third connection line 183 among the plurality of third connection lines 183 may connect the reference lines RL of the main plate pattern 121M and the sub-plate pattern 121S disposed in a left column of a column in which the main plate pattern 121M is disposed. For example, the reference line RL of the main plate pattern 121M disposed in column C and the reference line RL of the sub-plate pattern 121S in column B adjacent to column C may be connected through the third connection line 183. In this case, the reference line RL of the main plate pattern 121M and the reference line RL of the sub-plate pattern 121S may form a zigzag shape together with the third connection line 183. Accordingly, the sub-pixel of the main plate pattern 121M may share the reference line RL with the additional sub-pixel SPA of the sub-plate pattern 121S in a column adjacent thereto.

One second connection line 182 among the plurality of second connection lines 182 may connect the low potential power line PL2 on the main plate pattern 121M and the low potential power line PL2 on the sub-plate pattern 121S. The one second connection line 182 may connect the low potential power lines PL2 of the main plate pattern 121M and the sub-plate pattern 121S disposed in a row above a row in which the main plate pattern 121M is disposed. For example, the low potential power line PL2 of the main plate pattern 121M disposed in row C and the low potential power line PL2 of the sub-plate pattern 121S in row B adjacent to row C may be connected through the second connection line 182. The low potential power line PL2 of the main plate pattern 121M and the low potential power line PL2 of the sub-plate pattern 121S may form a zigzag shape together with the second connection line 182. Accordingly, the sub-pixel of the main plate pattern 121M may share the low potential power line PL2 with the additional sub-pixel SPA of the sub-plate patterns 121S in a row adjacent thereto.

Another second connection line 182 among the plurality of second connection lines 182 may connect the scan line SL on the main plate pattern 121M and the scan line SL on the sub-plate pattern 121S. Another second connection line 182 among the plurality of second connection lines 182 may connect the scan lines SL of the main plate pattern 121M and the sub-plate pattern 121S disposed in a row above a row in which the main plate pattern 121M is disposed. For example, the scan line SL of the main plate pattern 121M disposed in row C and the scan line SL of the sub-plate pattern 121S in row B adjacent to row C may be connected to each other through the second connection line 182. The scan line SL of the main plate pattern 121M and the scan line SL of the sub-plate pattern 121S may form a zigzag shape together with the second connection line 182. Accordingly, the sub-pixel of the main plate pattern 121M may share the scan line SL with the additional sub-pixel SPA of the sub-plate pattern 121S in a row adjacent thereto.

Still another second connection line 182 among the plurality of second connection lines 182 may connect the high potential power line PL1 on the main plate pattern 121M and the high potential power line PL1 on the sub-plate pattern 121S. The still another second connection line 182 may connect the high potential power lines PL1 of the main plate pattern 121M and the sub-plate pattern 121S disposed in a row below a row in which the main plate pattern 121M is disposed. For example, the high potential power line PL1 of the main plate pattern 121M disposed in row A and the high potential power line PL1 of the sub-plate pattern 121S in row B adjacent to row A may be connected through the second connection line 182. The high potential power line PL1 of the main plate pattern 121M and the high potential power line PL1 of the sub-plate pattern 121S may form a zigzag shape together with the second connection line 182. Thus, the sub-pixel of the main plate pattern 121M may share the high potential power line PL1 with the additional sub-pixel SPA of the sub-plate pattern 121S in a row adjacent thereto.

A remaining second connection line 182 among the plurality of second connection lines 182 may connect the emission control line EML on the main plate pattern 121M and the emission control line EML on the sub-plate pattern 121S. The remaining second connection line 182 may connect the emission control lines EML of the main plate pattern 121M and the sub-plate pattern 121S disposed in a row below a row in which the main plate pattern 121M is disposed. For example, the emission control line EML of the main plate pattern 121M disposed in row A and the emission control line EML of the sub-plate pattern 121S in row B adjacent to row A may be connected to each other through the second connection line 182. The emission control line EML of the main plate pattern 121M and the emission control line EML of the sub-plate pattern 121S may form a zigzag shape together with the second connection line 182. Accordingly, the sub-pixel of the main plate pattern 121M may share the emission control line EML with the additional sub-pixel SPA of the sub-plate pattern 121S in a row adjacent thereto.

Meanwhile, during a manufacturing process of the display device 100, a lighting test may be performed to check whether the sub-pixels operate normally. After the LEDs 170 are transferred to the plurality of sub-pixels, a defective sub-pixel may be detected by applying signals to the plurality of lines. In the case of the defective sub-pixel, the defective sub-pixel is repaired by removing the LED 170 and the adhesive layer AD and re-transferring a new LED 170 onto the connection pads CP. However, in a process of removing the LED 170 and the adhesive layer AD, the connection pads CP or other lines are damaged. So even if the new LED 170 is transferred to an area from which the LED 170 has been removed, it is difficult to drive normally. Therefore, in the display device 100 according to an exemplary embodiment of the present disclosure, the additional sub-pixel SPA is previously formed on the sub-plate pattern 121S, and when a defective sub-pixel occurs, the new LED 170 is transferred onto the sub-plate pattern 121S, so that the display device 100 can be repaired.

Hereinafter, a repair method of the display device 100 using the additional sub-pixel SPA will be described with reference to FIGS. 10 to 13.

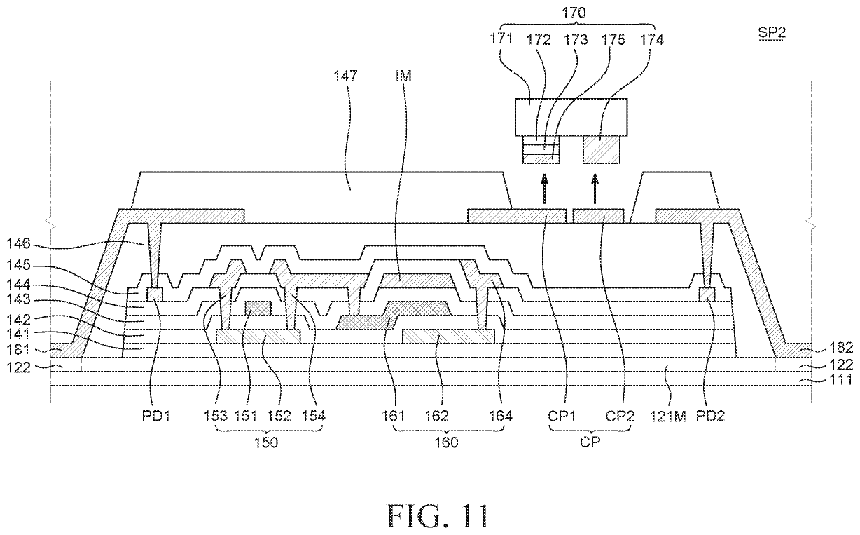

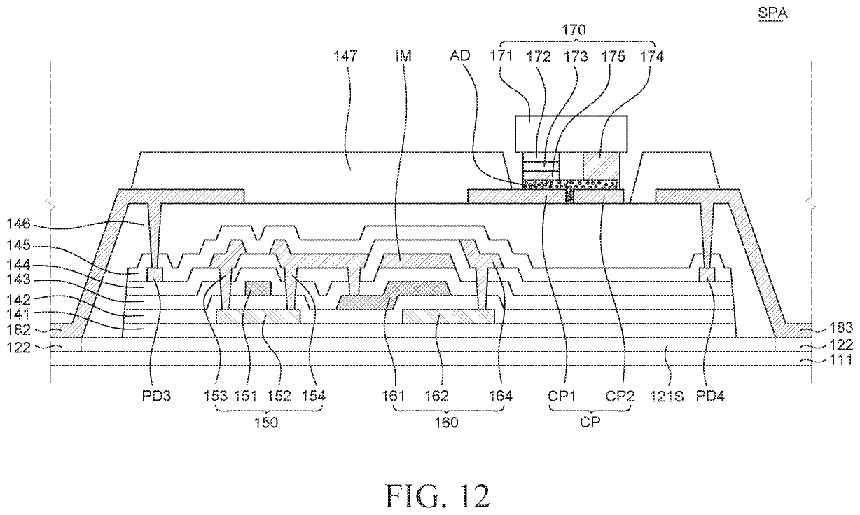

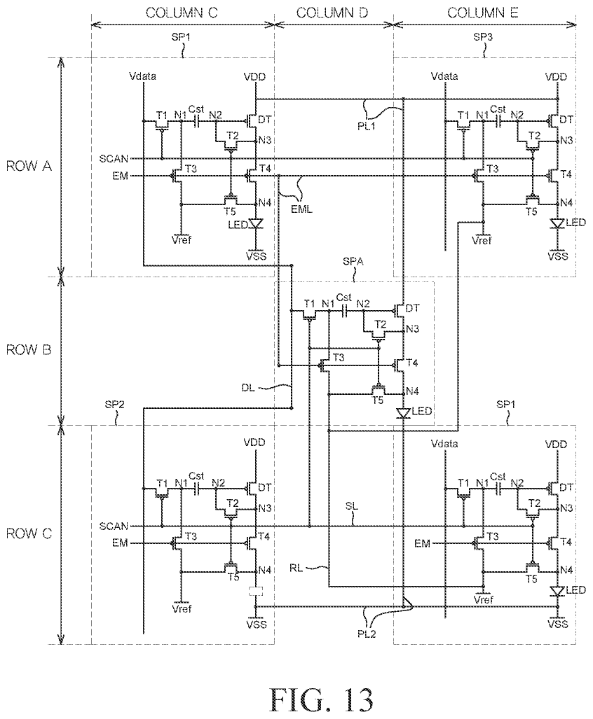

FIG. 10 is an enlarged plan view of the display device according to an exemplary embodiment of the present disclosure. FIG. 11 is a cross-sectional view of a defective sub-pixel of the display device according to an exemplary embodiment of the present disclosure. FIG. 12 is a cross-sectional view of an additional sub-pixel of the display device according to an exemplary embodiment of the present disclosure. FIG. 13 is a circuit diagram illustrating sub-pixels and an additional sub-pixel of the display device according to an exemplary embodiment of the present disclosure.

Referring to FIG. 10, when a defect occurs in the second sub-pixel SP2 of the main plate pattern 121M disposed in row C and column C, the display device 100 may be repaired by additionally transferring the LED 170 to one of the sub-plate patterns 121S adjacent to the corresponding main plate pattern 121M. For example, the display device 100 may be repaired by additionally transferring the LED 170 to one of the two sub-plate patterns 121S disposed in row B, which is an upper row of the main plate pattern 121M disposed in row C and column C. In addition, the display device 100 may be repaired by additionally transferring the LED 170 to one of the two sub-plate patterns 121S disposed in row D, which is a lower row of the main plate pattern 121M disposed in row C and column C.

In addition, the display device 100 may be repaired by preferentially transferring the LED 170 to the additional sub-pixel SPA sharing the scan line SL and data line DL with the defective sub-pixel. When the defective sub-pixel and the additional sub-pixel SPA share the scan lines SL and the data lines DL, the data voltage Vdata to be input to the defective sub-pixel may be input to the additional sub-pixel SPA instead, so that the additional sub-pixel SPA may emit light instead of the defective sub-pixel. Accordingly, the display device 100 may be repaired by selecting the additional sub-pixel SPA sharing the scan line SL and data line DL with the defective sub-pixel.

In this case, the sub-pixels sharing the scan line SL and data line DL with the additional sub-pixel SPA may vary according to the order in which the respective sub-pixels of the main plate pattern 121M are disposed. For example, when the plurality of sub-pixels are disposed in the order of the first sub-pixel SP1, the second sub-pixel SP2, and the third sub-pixel SP3 from a left side to a right side thereof in one main plate pattern 121M, the third sub-pixel SP3 may share the scan line SL and the data line DL with the additional sub-pixel SPA of the sub-plate pattern 121S disposed at an upper right portion thereof among the sub-plate patterns 121S adjacent thereto. For example, when the plurality of sub-pixels are disposed in the order of the second sub-pixel SP2, the third sub-pixel SP3, and the first sub-pixel SP1 in another main plate pattern 121M, the first sub-pixel SP1 may share the scan line SL and the data line DL with the additional sub-pixel SPA of the sub-plate pattern 121S disposed at an upper right portion thereof among the sub-plate patterns 121S adjacent thereto. When the plurality of sub-pixels are disposed in the order of the third sub-pixel SP3, the first sub-pixel SP1, and the second sub-pixel SP2 in still another main plate pattern 121M, the second sub-pixel SP2 may share the scan line SL and the data line DL with the additional sub-pixel SPA of the sub-plate pattern 121S disposed at an upper right portion thereof among the sub-plate patterns 121S adjacent thereto.

However, the order in which the plurality of sub-pixels are disposed on the main plate pattern 121M is not limited thereto, and a position of the additional sub-pixel SPA which is selected at the time of repair is also not limited thereto.

Hereinafter, descriptions are made assuming that the display device 100 is repaired by transferring the LED 170 to the sub-plate pattern 121S in row B and column D when the main plate pattern 121M in row C and column C is defective.

Referring to FIG. 11, the LED 170 and the adhesive layer AD are removed from the second sub-pixel SP2 where a defect occurs. When the filling layer 190 or the upper substrate 112 is disposed over the LED 170, a portion of the filling layer 190 and the upper substrate 112 is removed by irradiating a laser into an area thereof corresponding to the second sub-pixel SP2, and then, the LED 170 and the adhesive layer AD may be removed. However, if the filling layer 190 and the upper substrate 112 are not formed, the LED 170 and the adhesive layer AD may be removed by directly irradiating a laser onto the LED 170 and the adhesive layer AD. Therefore, by removing the LED 170 and the adhesive layer AD from the defective sub-pixel, abnormal driving in the defective sub-pixel can be prevented.

Meanwhile, although FIG. 11 illustrates that the LED 170 of the defective sub-pixel is removed, the LED 170 may not be removed depending on a type of defect. For example, when there occur open defects in which the p-electrode 175 and the n-electrode 174 of the LED 170 are misaligned with the first connection pad CP1 and the second connection pad CP2, respectively and are not connected therewith, the LED 170 cannot be driven because current does not flow through the LED 170. In this case, the LED 170 may be left as it is without removing it. On the other hand, when there occurs a short-circuit defect in which the p-electrode 175 and the n-electrode 174 of the LED 170 are connected to the same connection pad CP, that is, a short-circuit defect in which the p-electrode 175 and the n-electrode 174 of the LED 170 are electrically connected to each other, the LED 170 may be removed to prevent abnormal driving.

Next, referring to FIG. 12, the new LED 170 is transferred to the additional sub-pixel SPA of the sub-plate pattern 121S. The adhesive layer AD may be formed on the connection pads CP of the additional sub-pixel SPA, and the LED 170 may be transferred onto the adhesive layer AD. Accordingly, when the display device 100 is driven, light may be emitted from the additional sub-pixel SPA instead of the defective sub-pixel.

Referring to FIG. 13, the additional sub-pixel SPA of the sub-plate pattern 121S may include the same circuit as the sub-pixel and may be normally driven by sharing lines with the main-plate pattern 121M adjacent thereto.

Specifically, the additional sub-pixel SPA of the sub-plate pattern 121S may share lines with the sub-pixels of the main-plate patterns 121M in a row adjacent thereto. For example, the additional sub-pixel SPA in row B and column D may share the data lines DL with the first sub-pixel SP1 of the main plate pattern 121M in row A and column C and the second sub-pixel SP2 in row C and column C. At this time, since the second sub-pixel SP2 of the main plate pattern 121M in row C and column C is in a state in which the LED 170 is removed, it does not emit light even when the data voltage Vdata is applied to the data line DL. Instead, the data voltage Vdata is transferred from the data line DL to the additional sub-pixel SPA, so that the additional sub-pixel SPA can emit light instead of the second sub-pixel SP2 in row C and column C.

Further, the additional sub-pixel SPA may share the reference line RL with the sub-pixels of the main plate patterns 121M in row A and column E and in row C and column E. The reference line RL of the additional sub-pixel SPA may be connected to the reference line RL of the main plate pattern 121M in column E through the third connection line 183. The reference voltage Vref may be supplied to the third transistor T3 and the fifth transistor T5 of the additional sub-pixel SPA, so that the additional sub-pixel SPA may be normally driven.

The additional sub-pixel SPA may share the emission control line EML and the high potential power line PL1 with the sub-pixels of the main plate pattern 121M in row A. The emission control line EML of the additional sub-pixel SPA may be connected to the emission control line EML of the main plate pattern 121M in row A through the second connection line 182, and the additional sub-pixel SPA may emit light simultaneously with the sub-pixels in row A. The high potential power line PL1 of the additional sub-pixel SPA may be connected to the high potential power line PL1 of the main plate pattern 121M in row A through the second connection line 182, so that the high potential power voltage VDD may be supplied to the driving transistor DT of the additional sub-pixel SPA.

The additional sub-pixel SPA may share the scan line SL and the low potential power line PL2 with the sub-pixels of the main plate patterns 121M in row C. The additional sub-pixel SPA, simultaneously with the sub-pixels in row C may receive the scan signal SCAN, and the data voltage Vdata may be transmitted from the data line DL to the first node N1. In this case, the data voltage Vdata to be input to the second sub-pixel SP2 in row C and column C where a defect occurs may be input to the additional sub-pixel SPA instead, so that the additional sub-pixel SPA can be driven like the second sub-pixel SP2.

Therefore, the additional sub-pixel SPA may receive the data voltage Vdata based on the scan signal SCAN instead of the second sub-pixel SP2 where the defect occurs, and may share the emission control line EML, the reference line RL, the low potential power line PL2, and the high potential power line PL1 with the sub-pixels in the rows and columns adjacent thereto. Thus, the additional sub-pixel SPA can be normally driven.

Meanwhile, even if the LED 170 is not transferred to the additional sub-pixel SPA, a signal may be transmitted between the main plate patterns 121M adjacent to each other through the lines of the additional sub-pixel SPA. For example, the scan signal SCAN may be continuously transmitted to each of the main plate patterns 121M in the same row through the scan lines SL of the additional sub-pixel SPA. For example, the data voltage Vdata may be continuously transmitted to each of the main plate patterns 121M in the same column through the data lines DL of the additional sub-pixel SPA.

Therefore, in the display device 100 according to an exemplary embodiment of the present disclosure, the additional sub-pixel SPA is formed in an empty space between the main plate patterns 121M, that is, in a dummy area. Thus, when the display device 100 is defective, it can be repaired. The sub-plate pattern 121S having the additional sub-pixel SPA may be formed by utilizing remaining areas of the lower substrate 111 on which the main plate pattern 121M is not disposed. The display device 100 of the present disclosure is a stretchable display device that needs to secure a stretchable area to be stretched and a rigid area in which the main plate pattern 121M having the sub-pixels formed therein is disposed. Thus, its resolution increases, it is difficult to secure a separate repair area or redundancy area in addition to the stretchable area and the rigid area. However, in the case of utilizing an empty space where the main plate pattern 121M is not disposed, as in the present disclosure, design areas of the main plate patterns 121M and the connection lines 180 are not limited, and the sub-plate patterns 121S can be placed freely. Therefore, in the display device 100 according to an exemplary embodiment of the present disclosure, since the additional sub-pixels SPA for repair are formed by utilizing empty spaces between the main plate patterns 121M, it may be advantageous for high resolution.

In the display device 100 according to an exemplary embodiment of the present disclosure, even if the connection pad CP or the like is damaged in the process of removing the LED 170 from a defective sub-pixel, it is not limited thereto, and the display device 100 can be easily repaired by transferring the LED 170 to the additional sub-pixel SPA. When the LED 170 is transferred, the LED 170 may be misaligned with the connection pad CP due to a process error. In this case, since the LED 170 is not normally connected to the connection pad CP, a short-circuit defect may occur, and then, the LED 170 of the defective sub-pixel may be removed to prevent abnormal driving. However, in the process of removing the LED 170 and the adhesive layer AD, the connection pad CP or some components on the main plate pattern 121M may be damaged by the irradiated laser. Even if the LED 170 is newly transferred to the already damaged sub-pixel, it is difficult to drive the LED 170 normally. However, since the LED 170 is newly transferred to the additional sub-pixel SPA in the display device 100 according to an exemplary embodiment of the present disclosure, the display device 100 can be repaired regardless of damage occurring in the defective sub-pixel.

The exemplary embodiments of the present disclosure can also be described as follows:

According to an aspect of the present disclosure, there is provided a display device. The display device includes a stretchable lower substrate; a pattern layer disposed on the lower substrate and including a plurality of main plate patterns, a plurality of sub-plate patterns, and a plurality of line patterns; a plurality of sub-pixels disposed on each of the plurality of main plate patterns; an additional sub-pixel disposed on each of the plurality of sub-plate patterns; and a plurality of connection lines disposed on each of the plurality of line patterns to connect the plurality of sub-pixels and the additional sub-pixel. The additional sub-pixels of some sub-plate patterns among the plurality of sub-plate patterns include light emitting elements.

The plurality of main plate patterns may be disposed in a matrix form forming a plurality in rows and a plurality of columns, the plurality of sub-plate patterns may be disposed between the plurality of respective rows where the plurality of main plate patterns are disposed and between the plurality of respective columns where the plurality of main plate patterns are disposed.

The plurality of main plate patterns and the plurality of sub-plate patterns may be alternately disposed in a row direction and a column direction.

The plurality of sub-pixels may include at least one defective sub-pixel, and only remaining sub-pixels excluding the defective sub-pixel among the plurality of sub-pixels, may include the light emitting elements.

The main plate pattern on which the defective sub-pixel is disposed among the plurality of main plate patterns, may be disposed adjacent to the some sub-plate patterns including the light emitting elements.

The plurality of sub-pixels may include a first sub-pixel, a second sub-pixel, and a third sub-pixel, and each of the plurality of main plate patterns may have a different order in which the first sub-pixel, the second sub-pixel, and the third sub-pixel are disposed.

In some main plate patterns of the plurality of main plate patterns, the plurality of sub-pixels may be disposed in the order of the first sub-pixel, the second sub-pixel, and the third sub-pixel, and when the third sub-pixel is a defective sub-pixel, the light emitting elements may be disposed on sub-plate patterns in columns adjacent to the some main plate patterns among the plurality of sub-plate patterns.

In other some main plate patterns among the plurality of main plate patterns, the plurality of sub-pixels may be disposed in the order of the second sub-pixel, the third sub-pixel, and the first sub-pixel, and when the first sub-pixel is a defective sub-pixel, the light emitting elements may be disposed on sub-plate patterns in columns adjacent to the other some main plate patterns among the plurality of sub-plate patterns.

According to another aspect of the present disclosure, there is provided a display device. The display device includes a stretchable lower substrate; a pattern layer disposed on the lower substrate and including a plurality of main plate patterns, a plurality of sub-plate patterns, and a plurality of line patterns; a plurality of sub-pixels disposed on each of the plurality of main plate patterns and each including a pixel circuit; an additional sub-pixel disposed on each of the plurality of sub-plate patterns and including the pixel circuit; a plurality of lines disposed in each of the plurality of sub-pixels and the additional sub-pixel and connected to the pixel circuit; and a plurality of connection lines disposed on each of the plurality of line patterns and connecting the plurality of lines of the plurality of main plate patterns and the plurality of lines of the sub-plate patterns. The plurality of main plate patterns are disposed in different rows and different columns from those of the plurality of sub-plate patterns.

The plurality of lines may include a scan line supplying a scan signal to the pixel circuit; a data line supplying a data voltage to the pixel circuit; an emission control line supplying an emission control signal to the pixel circuit; a reference line supplying a reference voltage to the pixel circuit; a high potential power line supplying a high potential power voltage to the pixel circuit; and a low potential power line supplying a low potential power voltage to the pixel circuit.

The emission control line and the high potential power line of the main plate pattern disposed in row A among the plurality of main plate patterns may be electrically connected to the emission control lines and the high potential power lines of the plurality of sub-plate patterns disposed in row B, respectively, through the plurality of connection lines.

The scan line and the low potential power line of the main plate pattern disposed in row C among the plurality of main plate patterns may be electrically connected to the scan lines and the low potential power lines of the plurality of sub-plate patterns disposed in row B, respectively, through the plurality of connection lines.

The data line may be provided in plural and the plurality of data lines may be disposed in each of the plurality of main plate patterns. One of the plurality of data lines of the main plate pattern disposed in column A among the plurality of main plate patterns may be electrically connected to the data lines of the plurality of sub-plate patterns disposed in column B through the plurality of connection lines.

The reference line of the main plate pattern disposed in column C among the plurality of main plate patterns may be electrically connected to the reference lines of the plurality of sub-plate patterns disposed in column B through the plurality of connection lines.

In one main plate pattern among the plurality of main plate patterns, when any one of the plurality of sub-pixels is defective, a light emitting element connected to the pixel circuit may be disposed on the sub-plate pattern disposed in a row and column adjacent to the one main plate pattern.

The plurality of connection lines may include first connection lines extending in a column direction between the plurality of main plate patterns; second connection lines extending from left edges and right edges of the plurality of main plate patterns toward upper edges and lower edges of the plurality of sub-plate patterns; and third connection lines extending from upper edges and lower edges of the plurality of main plate patterns toward left edges and right edges of the plurality of sub-plate patterns.

The first connection lines may connect remaining data lines except for the one data line among the plurality of data lines on the plurality of main plate patterns to each other. The second connection lines may connect the scan lines, the emission control lines, the high potential power lines, and the low potential power lines on the plurality of main plate patterns and the plurality of sub-plate patterns to each other, and the third connection lines may connect the one data line and the reference lines on the plurality of main plate patterns and the plurality of sub-plate patterns to each other.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

What is claimed is:

1. A display device, comprising:
a stretchable lower substrate;
a pattern layer on the lower substrate, the pattern layer including a plurality of main plate patterns, a plurality of sub-plate patterns, and a plurality of line patterns;
a plurality of sub-pixels on each of the plurality of main plate patterns;
an additional sub-pixel on each of the plurality of sub-plate patterns; and
a plurality of connection lines on each of the plurality of line patterns, the plurality of connection lines connecting the plurality of sub-pixels and the additional sub-pixel,
wherein additional sub-pixels of some sub-plate patterns among the plurality of sub-plate patterns include light emitting elements.

2. The display device of claim 1, wherein the plurality of main plate patterns are disposed in a matrix form including a plurality in rows and a plurality of columns,
wherein the plurality of sub-plate patterns are between the plurality of respective rows where the plurality of main plate patterns are disposed and between the plurality of respective columns where the plurality of main plate patterns are disposed.

3. The display device of claim 1, wherein the plurality of main plate patterns and the plurality of sub-plate patterns are alternately disposed in a row direction and a column direction.

4. The display device of claim 1, wherein the plurality of sub-pixels include at least one defective sub-pixel,
wherein remaining sub-pixels excluding the defective sub-pixel among the plurality of sub-pixels include the light emitting elements.

5. The display device of claim 4, wherein a main plate pattern on which the defective sub-pixel is disposed among the plurality of main plate patterns is adjacent to the some sub-plate patterns including the light emitting elements.

6. The display device of claim 1, wherein the plurality of sub-pixels include a first sub-pixel, a second sub-pixel, and a third sub-pixel,
wherein each of the plurality of main plate patterns has a different order in which the first sub-pixel, the second sub-pixel, and the third sub-pixel are disposed.

7. The display device of claim 6, wherein in some main plate patterns of the plurality of main plate patterns, the plurality of sub-pixels are disposed in an order of the first sub-pixel, the second sub-pixel, and the third sub-pixel, and
responsive to the third sub-pixel being a defective sub-pixel, the light emitting elements are disposed on sub-plate patterns in columns adjacent to the some main plate patterns among the plurality of sub-plate patterns.

8. The display device of claim 7, wherein in other some main plate patterns among the plurality of main plate patterns, the plurality of sub-pixels are disposed in an order of the second sub-pixel, the third sub-pixel, and the first sub-pixel, and
responsive to the first sub-pixel being a defective sub-pixel, the light emitting elements are disposed on sub-plate patterns in columns adjacent to the other some main plate patterns among the plurality of sub-plate patterns.

9. A display device, comprising:
a stretchable lower substrate;
a pattern layer on the lower substrate, the pattern layer including a plurality of main plate patterns, a plurality of sub-plate patterns, and a plurality of line patterns;
a plurality of sub-pixels on each of the plurality of main plate patterns, each of the plurality of plurality of sub-pixels including a pixel circuit;
an additional sub-pixel on each of the plurality of sub-plate patterns, the additional sub-pixel including the pixel circuit;
a plurality of lines in each of the plurality of sub-pixels and the additional sub-pixel, the plurality of lines connected to pixel circuits of the plurality of sub-pixels and the additional sub-pixel; and
a plurality of connection lines on each of the plurality of line patterns, the plurality of connection lines connecting the plurality of lines of the plurality of main plate patterns and the plurality of lines of the sub-plate patterns,
wherein the plurality of main plate patterns are in different rows and different columns from those of the plurality of sub-plate patterns.

10. The display device of claim 9, wherein the plurality of lines include,
a scan line supplying a scan signal to the pixel circuit;
a data line supplying a data voltage to the pixel circuit;
an emission control line supplying an emission control signal to the pixel circuit;
a reference line supplying a reference voltage to the pixel circuit;
a high potential power line supplying a high potential power voltage to the pixel circuit; and
a low potential power line supplying a low potential power voltage to the pixel circuit.

11. The display device of claim 10, wherein the emission control line and the high potential power line of the main plate pattern disposed in a first row among the plurality of main plate patterns are electrically connected to emission control lines and the high potential power lines of the plurality of sub-plate patterns disposed in a second row, respectively, through the plurality of connection lines.

12. The display device of claim 11, wherein the scan line and the low potential power line of the main plate pattern disposed in a third row among the plurality of main plate patterns are electrically connected to scan lines and low potential power lines of the plurality of sub-plate patterns disposed in the second row, respectively, through the plurality of connection lines.

13. The display device of claim 12, wherein the data line includes a plurality of data lines and the plurality of data lines are disposed in each of the plurality of main plate patterns,
wherein one of the plurality of data lines of the main plate pattern disposed in a first column among the plurality of main plate patterns is electrically connected to data lines of the plurality of sub-plate patterns disposed in a second column through the plurality of connection lines.

14. The display device of claim 13, wherein the reference line of the main plate pattern disposed in a third column among the plurality of main plate patterns is electrically connected to reference lines of the plurality of sub-plate patterns disposed in the second column through the plurality of connection lines.

15. The display device of claim 14, wherein in one main plate pattern among the plurality of main plate patterns, responsive to any one of the plurality of sub-pixels being defective, a light emitting element connected to the pixel circuit is disposed on the sub-plate pattern disposed in a row and column adjacent to the one main plate pattern.

16. The display device of claim 14, wherein the plurality of connection lines include:
first connection lines extending in a column direction between the plurality of main plate patterns;
second connection lines extending from left edges and right edges of the plurality of main plate patterns toward upper edges and lower edges of the plurality of sub-plate patterns; and
third connection lines extending from upper edges and lower edges of the plurality of main plate patterns toward left edges and right edges of the plurality of sub-plate patterns.

17. The display device of claim 16, wherein the first connection lines connect remaining data lines from the plurality of data lines except for one data line among the plurality of data lines on the plurality of main plate patterns to each other,
wherein the second connection lines connect the scan lines, the emission control lines, the high potential power lines, and the low potential power lines on the plurality of main plate patterns and the plurality of sub-plate patterns to each other, and
wherein the third connection lines connect the one data line and the reference lines on the plurality of main plate patterns and the data line and the reference lines on the plurality of sub-plate patterns to each other.
